(19) United States
(12) Patent Application Publication
(10) Pub. No.: US 2016/0312113 A1
(43) Pub. Date: Oct. 27, 2016

(54) Optical Wavelength Conversion Element Containing Ionic Liquid, And Article Equipped With Said Optical Wavelength Conversion Element

(71) Applicants: NIPPON KAYAKU KABUSHIKIKAISHA, Tokyo (JP); TOKYO INSTITUTE OF TECHNOLOGY, Tokyo (JP)

(72) Inventors: Yoichi Murakami, Tokyo (JP); Toshiyuki Ito, Tokyo (JP); Ryoutarou Morita, Tokyo (JP); Kazuki Niimi, Tokyo (JP); Noriko Kiyoyanagi, Tokyo (JP)

(21) Appl. No.: 15/102,748

(22) PCT Filed: Nov. 21, 2014
(86) PCT No.: PCT/JP2014/080937

§ 371 Date: Jun. 8, 2016

(30) Foreign Application Priority Data
Dec. 13, 2013 (JP) 2013-258670
Jan. 31, 2014 (JP) 2014-017103

(51) Int. Cl. C09K 11/06; B01J 35/00; G02B 5/24; B01J 31/22; H01L 31/055; C09K 11/02; B01J 31/02

(52) U.S. Cl. CPC C09K 11/06; C09K 11/025; B01J 35/004; B01J 31/0285; B01J 31/02; B01J 31/2295; H01L 31/055; G02B 5/24; C09K 2211/185; C09K 2211/1011

(57) ABSTRACT

There is provided an optical wavelength conversion element with a good temporal stability and such a high optical wavelength conversion efficiency that the element is viable even under sunlight or similar, low intensity light. Owing to these properties, the element is suited for use in solar cells, photocatalysts, photocatalytic hydrogen and oxygen generating devices, photon upconversion filters, and like articles. The optical wavelength conversion element is visually homogeneous and transparent and produced by dissolving and/or dispersing in an ionic liquid (C) a combination of organic photosensitizing molecules (A) and organic light-emitting molecules (B) that exhibits triplet-triplet annihilation. When the ionic liquid (C) is washed with a volume of ultrapure water that is 9 times as much as the volume of the ionic liquid (C), the water resulting from the washing has a pH larger than 5.

### TECHNICAL FIELD

The present invention relates to an optical wavelength conversion element containing an ionic liquid and also relates to solar cells, photocatalysts, photocatalytic hydrogen and oxygen generating devices, photon upconversion filters, and like articles equipped with such an optical wavelength conversion element.

### BACKGROUND ART

In efforts to prevent global warming amid strong demands for clean alternative energy, new technology is urgently needed that is capable of efficiently converting sunlight to secondary energy (electric power, hydrogen, and the like). Expectations are growing for light-to-secondary energy conversion elements (i.e., elements converting light to secondary energy), such as solar cells and hydrogen generating photocatalysts, that exhibit a high light-to-secondary energy conversion efficiency (i.e., efficiency with which light is converted to secondary energy). In energy conversion, typical solar cells, hydrogen generating photocatalysts, and like light-to-secondary energy conversion elements utilize only part of the broad spectrum of sunlight below a certain threshold wavelength that is unique to the individual light-to-secondary energy conversion elements, failing to utilize those components that have longer wavelengths than the threshold wavelength. Thus, photon upconversion, in which the wavelengths of light are converted by absorbing relatively long wavelengths of light and emitting relatively short wavelengths of light, is being studied as one of technologies for effectively utilizing the broad spectrum of sunlight.

Research on photon upconversion by means of multiphoton absorption by rare-earth elements has a history of more than 50 years. Rare-earth elements, however, generally need very high incident light intensity for multiphoton absorption, which makes it difficult to target weak light, such as sunlight, for conversion in this method.

Several publications have been made recently about organic molecules capable of photon upconversion by means of light absorption and emission.

Patent Document 1 describes compositions by which photon energy upconversion takes place that contain at least a first component (e.g., phthalocyanine, a metal porphyrin, or a metal phthalocyanine) and a second component (e.g., a polyfluorene, an oligofluorene, a copolymer of these compounds, or a polyparaphenylene). The first component acts as a photon receptor that absorbs energy in a first wavelength range. The second component acts as a photon emitter that emits energy in a second wavelength range.

Non-patent Document 1 describes photon upconverters that exploit triplet-triplet annihilation (hereinafter, “TTA”) in organic molecules for upconversion of sunlight or similar, relatively weak light in a toluene solvent.

Some existent photon upconverters contain a high molecular weight organic polymer as a medium for organic molecules (see Non-patent Documents 2 and 3).

Patent Document 2 describes a photon upconversion system made up of at least one polymer and at least one sensitizer containing at least one type of heavy atoms, where the sensitizer has a higher triplet energy level than the polymer.

Non-patent Document 2 describes a photon upconverter that uses a polymer of cellulose acetate (molecular weight: about 100,000) as a dispersion medium for organic molecules.

Non-patent Document 3 describes a photon upconverter that uses, as a medium, a rubbery polymer with a glass transition temperature (Tg) of 236 K (−37° C.) that is soft at room temperature.

Non-patent Document 4 describes a photon upconverter that uses an oligomer of styrene (mixture of a trimer and a tetramer of styrene) as a medium for organic photosensitizing molecules and organic light-emitting molecules.

Non-patent Document 5 describes: metal porphyrins as organic photosensitizing molecules that can be used in TTA photon upconversion; diphenylanthracene, 9,10-bis(phenylethinyl)anthracene, and 9,10-bis(phenylethinyOnaphthacene as organic light-emitting molecules; and toluene as a medium for the organic photosensitizing and light-emitting molecules.

Non-patent Document 6 describes: a boron-dipyrromethene (BODIPY) derivative as a sensitizer for TTA photon upconversion; perylene or 1-chloro-9,10-bis(phenylethinyl)anthracene as an acceptor; and toluene as a medium.

The TTA-based photon upconverter, in principle, requires that organic molecules diffuse and collide with each other in a medium for energy transfer. Most prior art (Non-patent Documents 1, 4, 5, and 6) uses as a medium either a volatile organic solvent, such as toluene or benzene, or a highly volatile medium, such as a styrene oligomer. These volatile organic solvents and highly volatile media (e.g., styrene oligomers), however, create safety issues due to their flammability. They also forbid use of resin materials that, when used in or as a container for an optical wavelength conversion element, may dissolve in the media or swell due to permeation of the media, which is inconvenient.

TTA-based photon upconverters that use a polymer compound, such as cellulose acetate or a soft rubber, as a medium (Patent Document 2 and Non-patent Documents 2 and 3) have a problem that the upconversion emission intensity markedly decreases at room temperature (300 K) or below because the polymer compound is flammable and either solid or poorly fluidic at normal temperature (300 K). Non-patent Document 3 describes that the upconversion emission intensity is sufficiently high at relatively high temperatures (>300 K) where the polymer is sufficiently fluidic, but very low at low temperatures 300 K) where the medium is poorly fluidic because TTA photon upconversion requires that the organic molecules, responsible for producing triplet excitation energy, diffuse and collide with each other in a medium for energy transfer between the organic molecules.

To solve these issues/problems, the inventors of the present invention propose an optical wavelength conversion element for TTA photon upconversion produced by dissolving and/or dispersing organic photosensitizing molecules and organic light-emitting molecules in an ionic liquid. The proposed optical wavelength conversion element addresses conventional problems including the low upconversion emission intensity due to high viscosity of the medium, the flammability of the medium, and the volatility of the medium (Patent Document 3).

Optical wavelength conversion elements with a further improved optical wavelength conversion efficiency (upconversion quantum yield) that are viable even under sunlight or similar, low intensity light are in demand. Optical wavelength conversion elements with a good temporal stability are also in demand.

### CITATION LIST

### Patent Documents

Patent Document 1: JP 4518313 B
Patent Document 2: JP 2008-506798 A
Patent Document 3: WO 2012/050137 A

### Non-Patent Documents

Non-patent Document 1: S. Baluschev, et al., Physical Review Letters, vol. 97, pp. 143903-1 to 143903-3, 2006
Non-patent Document 2: A. Monguzzi, et al., Journal of Physical Chemistry A, vol. 113, pp. 1171-1174, 2009
Non-patent Document 3: Tanya N. Singh-Rachford, et al., Journal of the American Chemical Society, vol. 131, pp. 12007-12014, 2009
Non-patent Document 4: T. Miteva, et al., New Journal of Physics, vol. 10, pp. 103002-1-103002-10, 2008
Non-patent Document 5: S. Baluschev, et al., New Journal of Physics, vol. 10, pp. 013007-1-013007-12, 2008
Non-patent Document 6: W. Wu, et al., J. Org. Chem., 2011, 76, pp. 7056-7064

### SUMMARY OF THE INVENTION

### Problems to be Solved by the Invention

In view of these problems, it is an object of the present invention to provide an optical wavelength conversion element that has a good temporal stability and such a high optical wavelength conversion efficiency that the element is viable even under sunlight or similar, low intensity light and that therefore is suited for use in solar cells, photocatalysts, photocatalytic hydrogen and oxygen generating devices, photon upconversion filters, and like articles and to provide a solar cell, photocatalyst, photocatalytic hydrogen and oxygen generating device, photon upconversion filter, or like article equipped with the optical wavelength conversion element.

### Solution to Problem

The inventors of the present invention have diligently worked to solve the problems and as a result, have found that the object is achieved by a visually homogeneous and transparent optical wavelength conversion element that is produced by dissolving and/or dispersing in an ionic liquid (C) a combination of organic photosensitizing molecules (A) and organic light-emitting molecules (B) that exhibits TTA, where the ionic liquid (C) is a particular kind of ionic liquid, which has led to the completion of the invention.

More specifically, to address the problems, the present invention is directed to a visually homogeneous and transparent optical wavelength conversion element produced by dissolving and/or dispersing in an ionic liquid (C) a combination of organic photosensitizing molecules (A) and organic light-emitting molecules (B) that exhibits TTA, wherein water resulting from washing the ionic liquid (C) (water separated from the ionic liquid after washing) with a volume of ultrapure water that is 9 times as much as the volume of the ionic liquid (C) has a pH larger than 5.

According to this arrangement, when the ionic liquid (C) is washed with a volume of ultrapure water that is 9 times as much as the volume of the ionic liquid (C), the water resulting from the washing has a pH larger than 5. Therefore, the element has a good temporal stability and such a high optical wavelength conversion efficiency that the element is viable even under sunlight or similar, low intensity light, presumably for the following reasons. If the water resulting from washing an ionic liquid (e.g., some commercial ionic liquids) with a volume of ultrapure water that is 9 times as much as the volume of the ionic liquid has a pH of less than or equal to 5, the ionic liquid contains a relatively large amount of impurities including acidic impurities. This means that the ionic liquid has a poor temporal stability and that some of the impurities in the ionic liquid cause a decrease of the optical wavelength conversion efficiency of the optical wavelength conversion element. In contrast, the ionic liquid (C) used in the present invention, producing water with a pH larger than 5 when washed with a volume of ultrapure water that is 9 times as much as the volume of the ionic liquid (C), has a low acidic and other impurity content. Therefore, the ionic liquid (C) has a good temporal stability, and the impurities in the ionic liquid cause a limited decrease of the optical wavelength conversion efficiency of the optical wavelength conversion element. The optical wavelength conversion element in accordance with the present invention operates based on TTA and has a high optical wavelength conversion efficiency, and is hence viable even under sunlight or similar, low intensity light and suited for use in solar cells, photocatalysts, photocatalytic hydrogen and oxygen generating devices, photon upconversion filters, and like articles.

Additionally, the arrangement no longer uses the conventionally used media, such as flammable and highly volatile organic solvents (e.g., toluene and benzene), flammable, poorly fluidic, and highly viscous rubbery polymers, and flammable oligomers that have practically negligible vapor pressure. Instead, an ionic liquid is used that generally has extremely low vapor pressure, relatively high fluidity, flame retardance, and other favorable properties. The arrangement is therefore safe in practical use and is capable of sufficiently driving TTA by means of diffusion and mutual collision of the organic photosensitizing molecules (A) and the organic light-emitting molecules (B) by sufficiently dissolving and/or dispersing the organic photosensitizing molecules (A) and the organic light-emitting molecules (B) in the ionic liquid (C).

“Ultrapure water,” throughout this application, refers to water having an electric resistivity of greater than or equal to 15 MΩ·cm as measured by a method defined in JIS K 0552. “Visually homogeneous and transparent,” throughout this application, refers to visual absence of separation of a layer into two or more layers, visual absence of solids, visual homogeneousness, visual absence of turbidity and cloudiness, and visual transparency. Again throughout this application, “dissolve and/or disperse” refers to either “dissolve” or “disperse” or “concurrently dissolve and disperse.”

The present invention is also directed to a solar cell equipped with the optical wavelength conversion element. According to this arrangement, the solar cell has a high photoelectric conversion efficiency because the optical wavelength conversion element used has such a high optical wavelength conversion efficiency that the element is viable even under sunlight or similar, low intensity light.

The present invention is further directed to a photocatalyst equipped with the optical wavelength conversion element. According to this arrangement, the photocatalyst has a high catalytic efficiency because the optical wavelength conversion element used has such a high optical wavelength conversion efficiency that the element is viable even under sunlight or similar, low intensity light.

The present invention is yet further directed to a photocatalytic hydrogen and oxygen generating device equipped with the optical wavelength conversion element. According to this arrangement, the photocatalytic hydrogen and oxygen generating device has a high hydrogen and oxygen generating efficiency because the optical wavelength conversion element used has such a high optical wavelength conversion efficiency that the element is viable even under sunlight or similar, low intensity light.

The present invention is further directed to a photon upconversion filter converting light of relatively long wavelengths to light of relatively short wavelengths, the filter being equipped with: the optical wavelength conversion element; and a cell that serves as a sealing/holder shell, wherein the optical wavelength conversion element is sealed in the cell.

According to this arrangement, the photon upconversion filter has a high optical wavelength conversion efficiency because the optical wavelength conversion element used has such a high optical wavelength conversion efficiency that the element is viable even under sunlight or similar, low intensity light.

### Advantageous Effects of the Invention

The present invention provides an optical wavelength conversion element that has a good temporal stability and such a high optical wavelength conversion efficiency that the element is viable even under sunlight or similar, low intensity light and also provides articles equipped with the optical wavelength conversion element (solar cells, photocatalysts, photocatalytic hydrogen and oxygen generating devices, and photon upconversion filters).

### BRIEF DESCRIPTION OF DRAWINGS

FIG. 1 is a cross-sectional view of a solar cell in accordance with an example of the present invention.

FIG. 2 is a cross-sectional view of a photocatalyst in accordance with an example of the present invention.

FIG. 3 is a diagram showing the upconversion emission spectrum of an optical wavelength conversion element obtained in Example 1.

FIG. 4 is a diagram showing the absorption spectrum of the optical wavelength conversion element obtained in Example 1.

FIG. 5 is a diagram showing the upconversion emission spectra of optical wavelength conversion elements obtained in Example 2 and Comparative Example 2.

FIG. 6 is a diagram showing the absorption spectrum of the optical wavelength conversion element obtained in Example 2.

FIG. 7 is a diagram showing the absorption spectrum of the optical wavelength conversion element obtained in Comparative Example 2.

FIG. 8 is a diagram showing the normalized upconversion emission intensities (peak intensities and integral intensities) of the optical wavelength conversion elements obtained in Example 2 and Comparative Example 2.

FIG. 9 is a diagram showing the absorption spectrum of an optical wavelength conversion element obtained in Example 3.

FIG. 10 is a diagram showing the upconversion emission spectrum of the optical wavelength conversion element obtained in Example 3.

FIG. 11 is a diagram showing the absorption spectrum of an optical wavelength conversion element obtained in Example 4.

FIG. 12 is a diagram showing the upconversion emission spectrum of the optical wavelength conversion element obtained in Example 4.

FIG. 13 is a graph representing a relationship between the normalized upconversion emission intensities of optical wavelength conversion elements obtained in Example 5 and the viscosities of ionic liquids (C) used in the optical wavelength conversion elements.

FIG. 14 is an enlargement of a part of the graph in FIG. 13.

FIG. 15 is a diagram showing the absorption spectrum of an optical wavelength conversion element obtained in Example 5 using an Ionic Liquid #14.

FIG. 16 is a diagram showing the upconversion emission spectrum of the optical wavelength conversion element obtained in Example 5 using the Ionic Liquid #14.

FIG. 17 is a diagram showing the absorption spectrum of an optical wavelength conversion element obtained in Example 6.

FIG. 18 is a diagram showing the upconversion emission spectrum of the optical wavelength conversion element obtained in Example 6.

FIG. 19 is a graph representing a relationship between the normalized upconversion emission intensities of optical wavelength conversion elements obtained in Example 7 and the viscosities of ionic liquids (C) used in the optical wavelength conversion elements.

FIG. 20 is a diagram showing the upconversion emission spectra of optical wavelength conversion elements obtained in Examples 8 to 14.

FIG. 21 is a diagram showing changes in the upconversion emission intensities (peak emission intensities) versus changes in gel concentrations in the optical wavelength conversion elements obtained in Examples 8 to 14.

### MODE FOR CARRYING OUT THE INVENTION

The following will describe the present invention in more detail.

An optical wavelength conversion element in accordance with the present invention is visually homogeneous and transparent and produced by dissolving and/or dispersing in an ionic liquid (C) a combination of organic photosensitizing molecules (A) and organic light-emitting molecules (B) that exhibits TTA, and when the ionic liquid (C) is washed with a volume of ultrapure water that is 9 times as much as the volume of the ionic liquid (C), produces water with a pH larger than 5.

The organic photosensitizing molecules (A) and the organic light-emitting molecules (B) may be any molecular species provided that the combination of the molecules (A) and (B) exhibits TTA (TTA-based emission). The light absorption wavelength of the organic photosensitizing molecules (A) and the light emission wavelength of the organic light-emitting molecules (B) may be selected in any manner from the spectrum of sunlight. As an example, in an optical wavelength conversion element arranged to upconvert visible to near-infrared light, the organic photosensitizing molecules (A) may be π-conjugated molecules that have an absorption band in the visible to the near-infrared region, and the organic light-emitting molecules (B) may be π-conjugated molecules that have an emission band in the visible to the near-infrared region. The organic photosensitizing molecules (A) and the organic light-emitting molecules (B) may be selected from a broad range of low to high molecular species including aromatic π-conjugated system compounds, especially polycyclic aromatic π-conjugated system compounds, and the compounds described in, for example, Non-patent Document 5.

The organic photosensitizing molecules (A) may be any molecular species that has a local maximum absorption wavelength in the spectrum of sunlight, typically in the 200 nm to 1,000 nm range and preferably in the 500 nm to 700 nm range. This arrangement enables conversion of relatively long wavelengths of light that are not utilized in common solar cells, hydrogen generating photocatalysts, and like light-to-secondary energy conversion elements into relatively short wavelengths of light that are utilized in common light-to-secondary energy conversion elements. The arrangement hence enables effective use of the broad spectrum of sunlight by the light-to-secondary energy conversion element.

The organic photosensitizing molecules (A) may be any molecular species that, irrespective of whether being termed a pigment or not, absorbs light in the ultraviolet to the infrared region. Examples of the organic photosensitizing molecules (A) include, but are by no means limited to, acenaphthene derivatives, acetophenone derivatives, anthracene derivatives, diphenylacetylene derivatives, acridan derivatives, acridine derivatives, acridone derivatives, thioacridone derivatives, angelicin derivatives, anthracene derivatives, anthraquinone derivatives, azafluorene derivatives, azulene derivatives, benzyl derivatives, carbazole derivatives, coronene derivatives, sumanene derivatives, biphenylene derivatives, fluorene derivatives, perylene derivatives, phenanthrene derivatives, phenanthroline derivatives, phenazine derivatives, benzophenone derivatives, pyrene derivatives, benzoquinone derivatives, biacetyl derivatives, bianthranil derivatives, fullerene derivatives, graphene derivatives, carotin derivatives, chlorophyll derivatives, chrysene derivatives, cinnoline derivatives, coumarin derivatives, curcumin derivatives, dansylamide derivatives, flavone derivatives, fluorenone derivatives, fluorescein derivatives, helicene derivatives, indene derivatives, lumichrome derivatives, lumiflavin derivatives, oxadiazole derivatives, oxazole derivatives, periflanthene derivatives, perylene derivatives, phenanthrene derivatives, phenanthroline derivatives, phenazine derivatives, phenol derivatives, phenothiazine derivatives, phenoxazine derivatives, phthalazine derivatives, phthalocyanine derivatives, picene derivatives, porphyrin derivatives, porphycene derivatives, hemiporphycene derivatives, subphthalocyanine derivatives, psoralen derivatives, angelicin derivatives, purine derivatives, pyrene derivatives, pyrromethene derivatives, pyridylketone derivatives, phenylketone derivatives, pyridylketone derivatives, thienylketone derivatives, furanylketone derivatives, quinazoline derivatives, quinoline derivatives, quinoxaline derivatives, retinal derivatives, retinol derivatives, rhodamine derivatives, riboflavin derivatives, rubrene derivatives, squalene derivatives, stilbene derivatives, tetracene derivatives, pentacene derivatives, anthraquinone derivatives, tetracenequinone derivatives, pentacenequinone derivatives, thiophosgene derivatives, indigo derivatives, thioindigo derivatives, thioxanthene derivatives, thymine derivatives, triphenylene derivatives, triphenylmethane derivatives, triaryl derivatives, tryptophan derivatives, uracil derivatives, xanthene derivatives, ferrocene derivatives, azulene derivatives, biacetyl derivatives, terphenyl derivatives, terfuran derivatives, terthiophene derivatives, oligoaryl derivatives, fullerene derivatives, conjugated polyene derivatives, Group 14 element-containing condensed polycyclic aromatic compound derivatives, and condensed polycyclic heteroaromatic compound derivatives.

Specific examples of the organic photosensitizing molecules (A) include, but are by no means limited to, metal porphyrins (metal complexes of porphyrins); metal tetraaza porphyrins; metal phthalocyanines; iodine derivatives of 3,5-dimethyl-boron-dipyrromethene; boron-dipyrromethenes, such as iodine derivatives of 3,5-dimethyl-8-phenylboron-dipyrromethene; Schiff base metal complexes, such as salen metal complexes; metal bipyridine complexes, such as rubidium-bipyridine complexes and iridium-phenanthroline complexes; metal phenanthroline complexes; naphthalene diimides, such as N-alkyl naphthalene diimides; and acridones, such as N-methyl acridone. Examples of the metal atoms in the metal porphyrins and the metal phthalocyanines include Pt, Pd, Ru, Rh, Ir, Zn, and Cu. Examples of the metal tetraaza porphyrins include metal tetraaza porphyrins of general formula (5) (detailed later) with the carbon atoms at positions 5, 10, 15, and 20 and R⁸'s attached to those carbon atoms being replaced by nitrogen atoms.

Preferred exemplary compounds of the organic photosensitizing molecules (A) that have a local maximum absorption wavelength of from 500 nm to 700 nm include compounds of general formula (5)

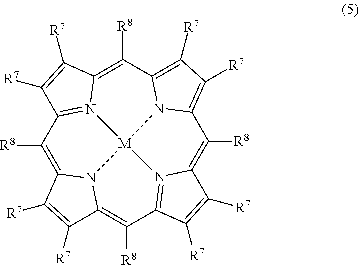

where each of R⁷'s is any substituent including a hydrogen atom and may be identical to or different from each other, adjacent R⁷'s may be joined together to form a five- or six-membered ring having any substituent including a hydrogen atom, each of R⁸'s is an aryl group containing any substituent including a hydrogen atom and may be identical to or different from each other, and M is a metal atom. “Any substituent including a hydrogen atom,” throughout this specification, refers to a hydrogen atom and any substituent that is not a hydrogen atom.

Examples of R⁷ in general formula (5) include, but are by no means limited to, a hydrogen atom, an alkyl group (e.g., C₁-C₁₂ alkyl group), an alkenyl group, an alkynyl group, a halogen atom, a hydroxy group, an alkylcarbonyloxy group, an arylcarbonyloxy group, an alkoxycarbonyloxy group, an aryloxycarbonyloxy group, a carboxylate group, an alkylcarbonyl group, an arylcarbonyl group, an alkoxycarbonyl group, an aminocarbonyl group, an alkylaminocarbonyl group, a dialkylaminocarbonyl group, an alkylthiocarbonyl group, an alkoxyl group, a phosphate group, a phosphonate group, a phosphinate group, a cyano group, an amino group (including an alkylamino group, a dialkylamino group, an arylamino group, a diarylamino group, and an alkylarylamino group), an acylamino group (including an alkylcarbonylamino group, an arylcarbonylamino group, a carbamoyl group, and a ureide group), an amidino group, an imino group, a sulfhydryl group, an alkylthio group, an arylthio group, a thiocarboxylate group, a sulfate group, an alkylsulfinyl group, a sulfonate group, a sulfamoyl group, a sulfonamide group, a nitro group, a trifluoromethyl group, a cyano group, an azide group, a heterocyclic group, an alkylaryl group, an aryl group, and a heteroaryl group. Examples of the substituent on the five- or six-membered ring formed by adjacent R⁷'s being joined together that may be in general formula (5) include, but are by no means limited to, the substituents listed here as examples of R⁷. The five- and six-membered ring may be attached to another porphyrin ring that may contain a substituent. Examples of R⁸ in general formula (5) include, but are by no means limited to, the substituents listed here as examples of R⁷. Examples of the metal atoms in the metal porphyrins and the metal phthalocyanines as the metal atom M in general formula (5) include Pt, Pd, Ru, Rh, Ir, Zn, and Cu.

Examples of the metal porphyrin of general formula (5) include meso-tetraphenyl-tetrabenzoporphyrin metal complexes, such as meso-tetraphenyl-tetrabenzoporphyrin palladium (CAS Number: 119654-64-7); octaethylporphyrin metal complexes, such as octaethylporphyrin palladium (CAS Number: 24804-00-0); and octaethylporphyrin metal complexes, such as meso-tetraphenyl-octamethoxy-tetranaphtho[2,3]porphyrin palladium described in Non-patent Document 5. Preferred among these examples are meso-tetraphenyl-tetrabenzoporphyrin metal complexes, such as meso-tetraphenyl-tetrabenzoporphyrin palladium, and octaethylporphyrin metal complexes, such as octaethylporphyrin palladium.

The organic photosensitizing molecules (A) preferably have a structure containing no metal. The absence of metal precludes environmental metal contamination during the manufacture and disposal of the optical wavelength conversion element.

Specific examples of the organic photosensitizing molecules having a structure containing no metal include C₇₀ and compounds (boron-dipyrromethenes) of general formula (1)

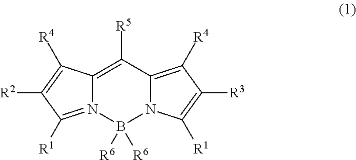

where each of R¹ to R⁵ is independently any substituent including a hydrogen atom, adjacent substituents (R¹ and R², R² and R⁴, R¹ and R³, and R³ and R⁴) may be joined together to form a five- or six-membered ring having any substituent including a hydrogen atom, and R⁶ is a halogen atom, a C₁-C₅ alkyl group that may contain a substituent, or a C₁-C₅ alkoxyl group that may contain a substituent.

Examples of R¹ to R⁵ in general formula (1) include, but are by no means limited to, a hydrogen atom, an alkyl group, an alkenyl group, an alkynyl group, a halogen atom, a hydroxy group, an alkylcarbonyloxy group, an arylcarbonyloxy group, an alkoxycarbonyloxy group, an aryloxycarbonyloxy group, a carboxylate group, an alkylcarbonyl group, an arylcarbonyl group, an alkoxycarbonyl group, an aminocarbonyl group, an alkylaminocarbonyl group, a dialkylaminocarbonyl group, an alkylthiocarbonyl group, an alkoxyl group, a phosphate group, a phosphonate group, a phosphinate group, a cyano group, an amino group (including an alkylamino group, a dialkylamino group, an arylamino group, a diarylamino group, and an alkylarylamino group), an acylamino group (including an alkylcarbonylamino group, an arylcarbonylamino group, a carbamoyl group, and a ureide group), an amidino group, an imino group, a sulfhydryl group, an alkylthio group, an arylthio group, a thiocarboxylate group, a sulfate group, an alkylsulfinyl group, a sulfonate group, a sulfamoyl group, a sulfonamide group, a nitro group, a trifluoromethyl group, a cyano group, an azide group, a heterocyclic group, an alkylaryl group, an aryl group, and a heteroaryl group. Examples of the substituent on the five- or six-membered ring formed by the adjacent substituents (R¹ and R², R² and R⁴, R¹ and R³, and R³ and R⁴) being joined together that may be in general formula (1) include, but are by no means limited to, the substituents listed here as examples of R¹ to R⁵.

Each of R¹ and R⁴ in general formula (1) is preferably a hydrogen atom, a halogen atom, a C₁-C₄ aliphatic hydrocarbon group that may contain a substituent, a phenyl group that may contain a substituent, a phenoxy group that may contain a substituent, a thienyl group that may contain a substituent, a thienoxy group that may contain a substituent, a 2-carboxylethenyl group of general formula (2)

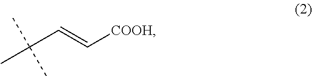

or

a 2-carboxyl-2-cyanoethenyl group of general formula (3)

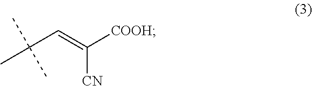

more preferably a C₁-C₃ alkyl group that may contain a substituent; even more preferably a non-substituted C₁-C₃ alkyl group; and most preferably a non-substituted methyl group.

Each of R² and R³ in general formula (1) is preferably a hydrogen atom, a halogen atom, a C₁-C₄ aliphatic hydrocarbon group that may contain a substituent, a phenyl group that may contain a substituent, a phenoxy group that may contain a substituent, a thienyl group that may contain a substituent, a thienoxy group that may contain a substituent, a 2-carboxylethenyl group of general formula (2), or a 2-carboxyl-2-cyanoethenyl group of general formula (3); more preferably a hydrogen atom, a bromine atom, or an iodine atom, in which case either one or both of R² and R³ must be a bromine atom or an iodine atom; and even more preferably a hydrogen atom or an iodine atom, in which case either one or both of R² and R³ must be an iodine atom.

R⁵ in general formula (1) is preferably a hydrogen atom, a halogen atom, a C₁-C₄ aliphatic hydrocarbon group that may contain a substituent, a phenyl group that may contain a substituent, a phenoxy group that may contain a substituent, a thienyl group that may contain a substituent, a thienoxy group that may contain a substituent, a 2-carboxylethenyl group of general formula (2), or a 2-carboxyl-2-cyanoethenyl group of general formula (3); more preferably a phenyl group that may contain a substituent; and even more preferably a non-substituted or alkyl-substituted phenyl group.

R⁶ in general formula (1) is a halogen atom, a C₁-C₅ alkyl group that may contain a substituent, or a C₁-C₅ alkoxyl group that may contain a substituent, and preferably a fluorine atom.

The organic photosensitizing molecules (A) are preferably a metal porphyrin of general formula (5) or a compound of general formula (1); more preferably a compound of general formula (1); even more preferably a compound of general formula (1) in which each of R¹ to R⁵ in general formula (1) is independently a hydrogen atom, a halogen atom, a C₁-C₄ aliphatic hydrocarbon group that may contain a substituent, a phenyl group that may contain a substituent, a phenoxy group that may contain a substituent, a thienyl group that may contain a substituent, a thienoxy group that may contain a substituent, a 2-carboxylethenyl group of general formula (2), or a 2-carboxyl-2-cyanoethenyl group of general formula (3); and most preferably a compound of general formula (4)

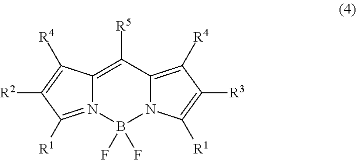

where each of R¹ and R⁴ is independently a C₁-C₃ alkyl group that may contain a substituent, each of R² and R³ is independently a hydrogen atom, a bromine atom, or an iodine atom, either one or both of R² and R³ is/are a bromine atom or an iodine atom, and R⁵ is a phenyl group that may contain a substituent. These compositions enable an optical wavelength conversion element with a further improved optical wavelength conversion efficiency.

Specific exemplary compounds of general formula (1) include a compound (2-iodo-1,3,5,7-tetramethyl-8-phenyl-4,4-difluoroboradiazaindacene) (local maximum absorption wavelength=510 nm) of the formula

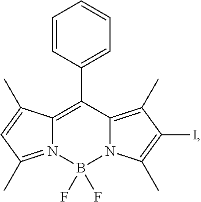

a compound (2,6-diiodo-1,3,5,7-tetramethyl-8-phenyl-4,4-difluoroboradiazaindacene) (local maximum absorption wavelength=529 nm) of the formula

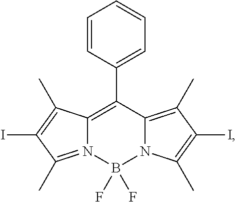

a compound (local maximum absorption wavelength=629 nm) of the formula

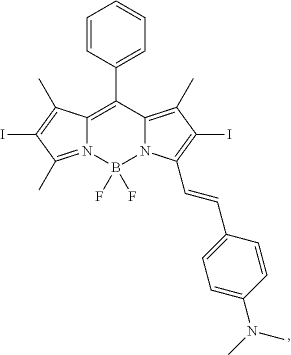

a compound (local maximum absorption wavelength=539 nm) of the formula

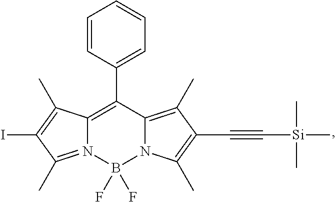

a compound (local maximum absorption wavelength=557 nm) of the formula

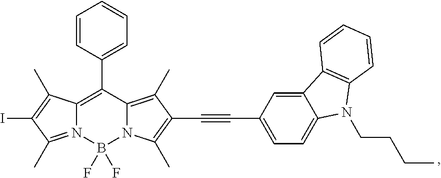

a compound (local maximum absorption wavelength=576 nm) of the formula

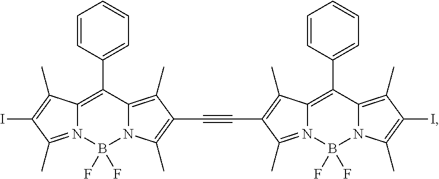

a compound (local maximum absorption wavelength=575 nm and 618 nm) of the formula

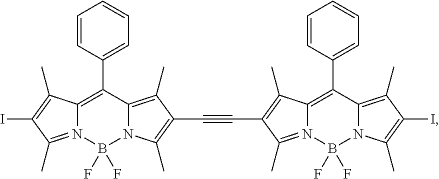

a compound (local maximum absorption wavelength=532 nm) of the formula

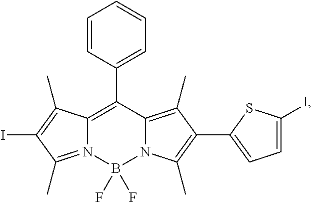

and

a compound (local maximum absorption wavelength=526 nm) of the formula

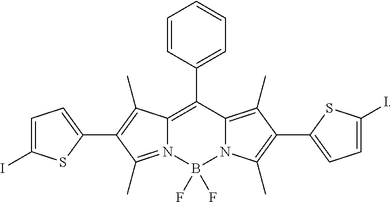

Any one of these examples of the organic photosensitizing molecules (A) may be used alone; alternatively, two or more of the examples may be used in the form of mixture.

The organic light-emitting molecules (B) may be any organic compound that emits TTA-upconverted light when used together with the organic photosensitizing molecules (A). Examples of the organic light-emitting molecules (B) include, but are by no means limited to, acenaphthene derivatives, acetophenone derivatives, anthracene derivatives, diphenylacetylene derivatives, acridan derivatives, acridine derivatives, acridone derivatives, thioacridone derivatives, angelicin derivatives, anthracene derivatives, anthraquinone derivatives, azafluorene derivatives, azulene derivatives, benzyl derivatives, carbazole derivatives, coronene derivatives, sumanene derivatives, biphenylene derivatives, fluorene derivatives, perylene derivatives, phenanthrene derivatives, phenanthroline derivatives, phenazine derivatives, benzophenone derivatives, pyrene derivatives, benzoquinone derivatives, biacetyl derivatives, bianthranil derivatives, fullerene derivatives, graphene derivatives, carotin derivatives, chlorophyll derivatives, chrysene derivatives, cinnoline derivatives, coumarin derivatives, curcumin derivatives, dansylamide derivatives, flavone derivatives, fluorenone derivatives, fluorescein derivatives, helicene derivatives, indene derivatives, lumichrome derivatives, lumiflavin derivatives, oxadiazole derivatives, oxazole derivatives, periflanthene derivatives, perylene derivatives, phenanthrene derivatives, phenanthroline derivatives, phenazine derivatives, phenol derivatives, phenothiazine derivatives, phenoxazine derivatives, phthalazine derivatives, phthalocyanine derivatives, picene derivatives, porphyrin derivatives, porphycene derivatives, hemiporphycene derivatives, subphthalocyanine derivatives, psoralen derivatives, angelicin derivatives, purine derivatives, pyrene derivatives, pyrromethene derivatives, pyridylketone derivatives, phenylketone derivatives, pyridylketone derivatives, thienylketone derivatives, furanylketone derivatives, quinazoline derivatives, quinoline derivatives, quinoxaline derivatives, retinal derivatives, retinol derivatives, rhodamine derivatives, riboflavin derivatives, rubrene derivatives, squalene derivatives, stilbene derivatives, tetracene derivatives, pentacene derivatives, anthraquinone derivatives, tetracenequinone derivatives, pentacenequinone derivatives, thiophosgene derivatives, indigo derivatives, thioindigo derivatives, thioxanthene derivatives, thymine derivatives, triphenylene derivatives, triphenylmethane derivatives, triaryl derivatives, tryptophan derivatives, uracil derivatives, xanthene derivatives, ferrocene derivatives, azulene derivatives, biacetyl derivatives, terphenyl derivatives, terfuran derivatives, terthiophene derivatives, oligoaryl derivatives, fullerene derivatives, conjugated polyene derivatives, Group 14 element-containing condensed polycyclic aromatic compound derivatives, and condensed polycyclic heteroaromatic compound derivatives.

Specific examples of the organic light-emitting molecules (B) include, but are by no means limited to, 9,10-diphenylanthracene (CAS Number: 1499-10-1) and derivatives thereof, 9,10-bis(phenylethinyl)anthracene (CAS Number: 10075-85-1) and derivatives thereof (e.g., 1-chloro-9,10-bis(phenylethinyl)anthracene), perylene (CAS Number: 198-55-0) and derivatives thereof (e.g., perylene diimides), pyrene and derivatives thereof, rubrene and derivatives thereof, naphthalene and derivatives thereof (e.g., naphthalene diimides, perfluoronaphthalene, 1-cyanonaphthalene, and 1-methoxynaphthalene), 9,10-bis(phenylethinyl)naphthacene, 4,4′-bis(5-tetracenyl)-1,1′-biphenylene, indoles, benzofurans, benzothiophenes, biphenyl, bifurans, bithiophene, and 4,4-difluoro-4-bora-3a,4a-diaza-s-indacene (boron-dipyrromethene). The organic light-emitting molecules (B) are preferably condensed polycyclic aromatic compounds, such as perylene, pyrene, anthracene, and derivatives thereof. Any one of these examples of the organic light-emitting molecules (B) may be used alone; alternatively, two or more of the examples may be used in the form of mixture.

The optical wavelength conversion element in accordance with the present invention may contain the organic photosensitizing molecules (A) and the organic light-emitting molecules (B) in any amounts. However, both the amount of the organic photosensitizing molecules (A) and the amount of the organic light-emitting molecules (B) are typically from 0.000001 to 10 parts by mass, preferably from 0.00001 to 5 parts by mass, and more preferably from 0.0001 to 1 part by mass, all per 100 parts by mass of the optical wavelength conversion element.

The ionic liquid (C) is a room temperature molten salt (salt that is molten (a liquid) at normal temperature (25° C.)) composed of cations and anions. Combinations of cations and anions can generally produce more than 1,000,000 compounds that are known as ionic liquids. The ionic liquid (C) functions as a medium for the organic photosensitizing molecules (A) and the organic light-emitting molecules (B), a combination that exhibits TTA. The ionic liquid (C) allows therein diffusion of the organic photosensitizing molecules (A) and the organic light-emitting molecules (B).

In the optical wavelength conversion element in accordance with the present invention, the organic photosensitizing molecules (A) and the organic light-emitting molecules (B), a combination that exhibits TTA, need to dissolve and/or disperse in the ionic liquid (C) so that the molecules (A) and (B) become visually homogeneous and transparent. Therefore, the ionic liquid (C) preferably undergoes cation-π interaction with the organic photosensitizing molecules (A) and the organic light-emitting molecules (B) and is water-immiscible. Throughout this specification, the ionic liquid (C) being “water-immiscible” means that at 25° C., the ionic liquid (C) may mix with 50 mass % or less water to produce a visually homogeneous and transparent mixture (e.g., the ionic liquid (C) may mix with 5 mass % or less water to produce a visually homogeneous and transparent mixture), but the ionic liquid (C) does not mix with more than 50 mass % water to produce a visually homogeneous and transparent mixture.

Specific examples of the cations that constitute the ionic liquid (C) include cations of nitrogen-containing compounds, quaternary phosphonium cations, and sulfonium cations. Examples of the cations of nitrogen-containing compounds include heterocyclic aromatic amine cations, such as imidazolium cations and pyridinium cations; heterocyclic aliphatic amine cations, such as piperidinium cations, pyrrolidinium cations, pyrazolium cations, thiazolium cations, and morpholinium cations; quaternary ammonium cations; aromatic amine cations; aliphatic amine cations; and alicyclic amine cations. Examples of the imidazolium cations include 1-alkyl-3-methylimidazoliums, such as 1-ethyl-3-methylimidazolium, 1-butyl-3-methylimidazolium, 1-hexyl-3-methylimidazolium, and 1-octyl-3-methylimidazolium; 1-alkyl-2,3-dimethylimidazoliums, such as 1-ethyl-2,3-dimethylimidazolium, 1-propyl-2,3-dimethylimidazolium, 1-butyl-2,3-dimethylimidazolium, 1-pentyl-2,3-dimethylimidazolium, 1-hexyl-2,3-dimethylimidazolium, 1-heptyl-2,3-dimethylimidazolium, and 1-octyl-2,3-dimethylimidazolium; 1-cyanomethyl-3-methylimidazolium; and 1-(2-hydroxyethyl)-3-methylimidazolium. Examples of the pyridinium cations include 1-butylpyridinium, 1-hexylpyridinium, N-(3-hydroxypropyl)pyridinium, and N-hexyl-4-dimethylamino pyridinium. Examples of the piperidinium cations include 1-(methoxyethyl)-1-methylpiperidinium. Examples of the pyrrolidinium cations include 1-(2-methoxyethyl)-1-methylpyrrolidinium and N-(methoxyethyl)-1-methylpyrrolidinium. Examples of the morpholinium cations include N-(methoxyethyl)-N-methylmorpholium. Examples of the quaternary ammonium cations include N,N-diethyl-N-methyl-N-(2-methoxyethyl)ammonium and N-ethyl-N,N-dimethyl-2-methoxyethylammonium. Examples of the quaternary phosphonium cations include tetraalkyl phosphonium and tetraphenylphosphonium. Examples of the sulfonium cations include trialkylsulfonium and triphenylsulfonium. The ionic liquid (C) may contain either a single one of these types of cations or two or more of these types of cations.

Taking into consideration the dissolution and dispersion stability of the organic photosensitizing molecules (A) and the organic light-emitting molecules (B) in the ionic liquid (C), the cations that constitute the ionic liquid (C) preferably undergo cation-π interaction with the organic photosensitizing molecules (A) and the organic light-emitting molecules (B).

Examples of the anions that constitute the ionic liquid (C), by no means limited in any particular manner, include fluorine-containing compound anions, such as bis(trifluoromethylsulfonyl)imide anions ([N(SO₂CF₃)₂]⁻), tris(trifluoromethylsulfonyl)methide anions ([C(SO₂CF₃)₃]⁻), hexafluorophosphate anions ([PF₆]⁻), tris(pentafluoroethyl), and trifluorophosphate anions ([(C₂F₅)₃PF₃]⁻); boron-containing compound anions of [BR¹¹R¹²R¹³R¹⁴], (in this and subsequent structural formulae of anions, each of R¹¹, R¹², R¹³, and R¹⁴ is independently a group of —(CH₂)ₙCH₃ (where n is an integer from 1 to 9), i.e., a C₁-C₉ linear alkyl group or aryl group); and bis(fluorosulfonyl)imide anions ([N(FSO₂)₂]⁻). The ionic liquid (C) may contain either a single one of these types of anions or two or more of these types of anions.

Generally, ionic liquids containing a certain class of anions may mix with water in unlimited amounts, whilst those containing another class of anions may mix with water only in limited amounts or in very small amounts. In the present invention, taking into consideration the dissolution and dispersion stability of the organic photosensitizing molecules (A) and the organic light-emitting molecules (B) in the ionic liquid (C), the anions that constitute the ionic liquid (C) preferably impart water-immiscibility to the ionic liquid.

The ionic liquid (C) may be any combination of the aforementioned specific examples of anions and the aforementioned specific examples of cations. More specific examples of the ionic liquid (C) include, but are by no means limited to, 1-ethyl-3-methylimidazolium bis(trifluoromethylsulfonyl)imide (CAS Number: 174899-82-2; for example, manufactured by and commercially available from Ionic Liquids Technologies GmbH), 1-propyl-2,3-dimethylimidazolium bis(trifluoromethylsulfonyl)imide (CAS Number: 169051-76-7; for example, manufactured by and commercially available from Ionic Liquids Technologies GmbH and also from Merck KGaA), 1-butyl-3-methylimidazolium bis(trifluoromethylsulfonyl)imide (CAS Number: 174899-83-3; for example, manufactured by and commercially available from Ionic Liquids Technologies GmbH and also from Merck KGaA), 1-propyl-2,3-dimethylimidazolium tris(trifluoromethylsulfonyl)methide (CAS Number: 169051-77-8; for example, manufactured by and commercially available from Covalent Associates Inc.), N,N-diethyl-N-methyl-N-(2-methoxyethyl)ammonium bis(trifluoromethylsulfonyl)imide (CAS Number: 464927-84-2; for example, manufactured by Nisshinbo Holdings Inc. and commercially available from Kanto Chemical Co., Inc. (Product number: 11468-55)), 1-hexyl-3-methylimidazolium bis(trifluoromethylsulfonyl)imide (CAS Number: 382150-50-7; for example, manufactured by and commercially available from Merck KGaA), 1-octyl-3-methylimidazolium bis(trifluoromethylsulfonyl)imide (CAS Number: 178631-04-4; for example, manufactured by Nisshinbo Holdings Inc. and commercially available from Kanto Chemical Co., Inc. (Product number: 49514-85)), 1-ethyl-2,3-dimethylimidazolium bis(trifluoromethylsulfonyl)imide (CAS Number: 174899-90-2; for example, commercially available from Kanto Chemical Co., Inc. (Product number: 49515-52)), 1-butyl-2,3-dimethylimidazolium bis(trifluoromethylsulfonyl)imide (CAS Number: 350493-08-2; for example, manufactured by and commercially available from Ionic Liquids Technologies GmbH and also from Merck KGaA), ethyl-dimethyl-propylammonium bis(trifluoromethylsulfonyl)imide (CAS Number: 258273-77-7; for example, manufactured by and commercially available from Merck KGaA), 1-ethyl-3-methylimidazolium tris(pentafluoroethyl) trifluorophosphate (CAS Number: 377739-43-0; for example, manufactured by and commercially available from Merck KGaA), 1-hexyl-3-methylimidazolium tris(pentafluoroethyl) trifluorophosphate (CAS Number: 713512-19-7; for example, manufactured by and commercially available from Merck KGaA), 1-butyl-1-methylpyrrolidinium bis(trifluoromethylsulfonyl)imide (CAS Number: 223437-11-4; for example, manufactured by and commercially available from Merck KGaA), 1-butyl-1-methylpyrrolidinium tris(pentafluoroethyl) trifluorophosphate (CAS Number: 851856-47-8; for example, manufactured by and commercially available from Merck KGaA), methyltri-n-octylammonium bis(trifluoromethylsulfonyl)imide (CAS Number: 375395-33-8; for example, manufactured by and commercially available from Merck KGaA), 1-ethyl-3-methylimidazolium tris(trifluoromethylsulfonyl)methide, 1-butyl-3-methylimidazolium tris(trifluoromethylsulfonyl)methide, 1-hexyl-3-methylimidazolium tris(trifluoromethylsulfonyl)methide, 1-octyl-3-methylimidazolium tris(trifluoromethylsulfonyl)methide, 1-butyl-2,3-dimethylimidazolium tris(trifluoromethylsulfonyl)methide, N,N-diethyl-N-methyl-N-(2-methoxyethyl)ammonium tris(trifluoromethylsulfonyl)methide, 1-butyl-3-methylimidazolium tris(pentafluoroethyl) trifluorophosphate, 1-octyl-3-methylimidazolium tris(pentafluoroethyl) trifluorophosphate, 1-propyl-2,3-dimethylimidazolium tris(pentafluoroethyl) trifluorophosphate, 1-butyl-2,3-dimethylimidazolium tris(pentafluoroethyl) trifluorophosphate, N,N-diethyl-N-methyl-N-(2-methoxyethyl)ammonium tris(pentafluoroethyl) trifluorophosphate, 1-ethyl-3-methylimidazolium hexafluorophosphate, 1-butyl-3-methylimidazolium hexafluorophosphate, 1-hexyl-3-methylimidazolium hexafluorophosphate, 1-octyl-3-methylimidazolium hexafluorophosphate, 1-propyl-2,3-dimethylimidazolium hexafluorophosphate, 1-butyl-2,3-dimethylimidazolium hexafluorophosphate, N,N-diethyl-N-methyl-N-(2-methoxyethyl)ammonium hexafluorophosphate, 1-ethyl-3-methylimidazolium [BR¹¹R¹²R¹³R¹⁴]⁻, 1-butyl-3-methylimidazolium [BR¹¹R¹²R¹³R¹⁴]⁻, 1-hexyl-3-methylimidazolium [BR¹¹R¹²R¹³R¹⁴]⁻, 1-octyl-3-methylimidazolium [BR¹¹R¹²R¹³R¹⁴]⁻, 1-propyl-2,3-dimethylimidazolium [BR¹¹R¹²R¹³R¹⁴]⁻, 1-butyl-2,3-dimethylimidazolium [BR¹¹R¹²R¹³R¹⁴]⁻, N,N-diethyl-N-methyl-N-(2-methoxyethyl)ammonium [BR¹¹R¹²R¹³R¹⁴]⁻, 1-butylpyridinium hexafluorophosphate, 1-hexylpyridinium hexafluorophosphate, 1-cyanomethyl-3-methylimidazolium bis(trifluoromethylsulfonyl)imide, N-hexyl-4-dimethylamino pyridinium bis(trifluoromethylsulfonyl)imide, 1-(2-hydroxyethyl)-3-methylimidazolium bis(trifluoromethylsulfonyl)imide, N-(3-hydroxypropyl)pyridinium bis(trifluoromethylsulfonyl)imide, N-ethyl-N,N-dimethyl-2-methoxyethylammonium tris(pentafluoroethyl) trifluorophosphate, 1-(2-hydroxyethyl)-3-methylimidazolium tris(pentafluoroethyl) trifluorophosphate, N-(3-hydroxypropyl)pyridinium tris(pentafluoroethyl) trifluorophosphate, N-(methoxyethyl)-N-methylmorpholium tris(pentafluoroethyl) trifluorophosphate, 1-(2-methoxyethyl)-1-methyl-pyrrolidinium tris(pentafluoroethyl) trifluorophosphate, 1-(methoxyethyl)-1-methylpiperidinium tris(pentafluoroethyl) trifluorophosphate, 1-(methoxyethyl)-1-methylpiperidinium bis(trifluoromethylsulfonyl)imide, N-(methoxyethyl)-1-methylpyrrolidinium bis(trifluoromethylsulfonyl)imide, and N-(methoxyethyl)-N-methylmorpholium bis(trifluoromethylsulfonyl). Any one of these examples of the ionic liquid (C) may be used alone; alternatively, two or more of the examples may be used in the form of mixture.

In the present invention, taking into consideration the dissolution and dispersion stability of the organic photosensitizing molecules (A) and the organic light-emitting molecules (B) in the ionic liquid (C), those preferred among the examples of the ionic liquid (C) listed above are combinations of the cations that undergo cation-π interaction with the organic photosensitizing molecules (A) and the organic light-emitting molecules (B) and the anions that impart water-immiscibility to the ionic liquid and are by itself water-immiscible.

Among the specific examples of the ionic liquid (C) listed above, those especially preferred include 1-ethyl-3-methylimidazolium bis(trifluoromethylsulfonyl)imide, 1-propyl-2,3-dimethylimidazolium bis(trifluoromethylsulfonyl)imide, 1-butyl-3-methylimidazolium bis(trifluoromethylsulfonyl)imide, 1-propyl-2,3-dimethylimidazolium tris(trifluoromethylsulfonyl)methide, N,N-diethyl-N-methyl-N-(2-methoxyethyl)ammonium bis(trifluoromethylsulfonyl)imide, 1-hexyl-3-methylimidazolium bis(trifluoromethylsulfonyl)imide, 1-octyl-3-methylimidazolium bis(trifluoromethylsulfonyl)imide, 1-ethyl-2,3-dimethylimidazolium bis(trifluoromethylsulfonyl)imide, 1-butyl-2,3-dimethylimidazolium bis(trifluoromethylsulfonyl)imide, ethyl dimethyl propylammonium bis(trifluoromethylsulfonyl)imide, 1-ethyl-3-methylimidazolium tris(pentafluoroethyl) trifluorophosphate, 1-hexyl-3-methylimidazolium tris(pentafluoroethyl) trifluorophosphate, 1-butyl-1-methylpyrrolidinium bis(trifluoromethylsulfonyl)imide, 1-butyl-1-methylpyrrolidinium tris(pentafluoroethyl) trifluorophosphate, and methyltri-n-octylammonium bis(trifluoromethylsulfonyl)imide.

The ionic liquid (C), at 26° C., has a viscosity of typically 10 mPa·s or greater, preferably 50 mPa·s or greater, and more preferably 70 mPa·s or greater. These viscosity values enable an optical wavelength conversion element with a further improved optical wavelength conversion efficiency.

The ionic liquid (C) in the optical wavelength conversion element in accordance with the present invention produces water with a pH larger than 5 when washed with a volume of ultrapure water that is 9 times as much as the volume of the ionic liquid. This property enables an optical wavelength conversion element with a further improved optical wavelength conversion efficiency and a further improved temporal stability. The pH of the water produced when the ionic liquid (C) is washed with a volume of ultrapure water that is 9 times as much as the volume of the ionic liquid (C) is measured by adding to the ionic liquid (C) a volume of ultrapure water that is 9 times as much as the volume of the ionic liquid (C) (9 times as much in volume ratio as the volume of the ionic liquid (C)), stirring the resultant mixture, thereafter separating out an aqueous layer, and then measuring the pH of the aqueous layer as the pH of interest.

Many commercial ionic liquids produce acid water with a pH of less than or equal to 5 when the ionic liquids are washed with a volume of ultrapure water that is 9 times as much as the volume of the ionic liquids. If such a commercial ionic liquid is to be used, impurities need to be removed from the commercial ionic liquid before use in order to obtain an ionic liquid (C) that, when washed with a volume of ultrapure water that is 9 times as much as the volume of the ionic liquid (C), produces water with a pH larger than 5.

Impurities may be removed from the ionic liquid, for example, by one of the following six methods. (1) The ionic liquid is processed with activated charcoal. (2) The ionic liquid is washed with water. (3) The ionic liquid is washed with an organic solvent (see, for example, JP 2012-144441 A). (4) The ionic liquid is dissolved in a solvent to obtain a solution, and the solution is cooled to crystallize the ionic liquid in the solution and then filtered to separate out the crystallized ionic liquid (recrystallization; see, for example, JP 2010-184902 A). (5) The ionic liquid is dissolved in a solvent to obtain a solution, and the solution is passed through a column filled with a filling agent, such as alumina (column chromatography; for example, JP 2005-314332 A). (6) The ionic liquid is processed with a metal hydride (see, for example, JP 2005-89313 A). Two or more of these methods may be used in any combination. For example, method (2) may be implemented by adding water (preferably, ultrapure water) to the ionic liquid, stirring the resultant mixture, removing an aqueous layer, and repeating this washing process until the water resulting from the washing comes to have a pH larger than 5. Thereafter, the liquid mixture is heated under reduced pressure to distill (dry) off water.

The optical wavelength conversion element in accordance with the present invention can be produced by dissolving and/or dispersing the organic photosensitizing molecules (A) and the organic light-emitting molecules (B) in the ionic liquid (C) by a conventional, publicly known technique to obtain a solution or dispersion liquid. In this method, where necessary, various additives may be additionally mixed with the organic photosensitizing molecules (A) and the organic light-emitting molecules (B) in the ionic liquid (C) by a conventional, publicly known technique to obtain a solution or dispersion liquid. In addition, in the same method, where necessary, the organic photosensitizing molecules (A) and the organic light-emitting molecules (B) may be ground to fine particles in a single publicly known disperser, such as an ultrasonic disperser, a bead mill, a homogenizer, a wet jet mill, a ball mill, an attritor, a sand mill, a roll mill, or a microwave disperser, or any combination of these dispersers, for fine dispersion in order to obtain a solution or dispersion liquid.

The optical wavelength conversion element in accordance with the present invention may be produced by other methods. As an example, first, the organic photosensitizing molecules (A) and the organic light-emitting molecules (B) are dissolved and/or dispersed in a volatile organic solvent. The obtained solution and/or dispersion fluid is then mixed with the ionic liquid (C) while stirring to prepare a visually homogeneous and transparent solution and/or dispersion fluid from which the volatile organic solvent is removed under reduced pressure until only a trace amount of the volatile organic solvent is left. This method, capable of readily delivering optical wavelength conversion elements that mix well until being homogeneous and transparent with a high stability and optical wavelength conversion efficiency, is a preferred method to obtain the optical wavelength conversion element in accordance with the present invention.

The volatile organic solvent used in this method may be any organic solvent that can dissolve and/or disperse the organic photosensitizing molecules (A) and the organic light-emitting molecules (B), mix with the ionic liquid (C) in such a manner as to produce a homogeneous and transparent mixture, and is so volatile that the organic solvent can be removed under reduced pressure until practically a trace amount of the volatile organic solvent is left. A “trace amount” of the volatile organic solvent being left, throughout this specification, means that the volatile organic solvent in the ionic liquid (C) does not stand out above noise levels and is hardly detectable in absorption spectrum measurement. The volatile organic solvent is preferably capable of dissolving the organic photosensitizing molecules (A) and the organic light-emitting molecules (B). The volatile organic solvent may be, for example, an aromatic solvent, such as toluene, benzene, or xylene. If a volatile organic solvent is to be used that is capable of dissolving the organic photosensitizing molecules (A) and the organic light-emitting molecules (B), a suitable volatile organic solvent may be selected that suits the solubility of the organic photosensitizing molecules and the organic light-emitting molecules.

The mixing and stirring described above may involve the use of a publicly known technique or device, such as ultrasound, bubbling, a stirrer, a liquid delivery pump, a pulverizer, a bead mill, a homogenizer, a wet jet mill, or microwave. Any one of these techniques and devices may be used alone; alternatively, two or more of the techniques and devices may be used in any combination.

The optical wavelength conversion element in accordance with the present invention may further contain a gelator (D). Optical wavelength conversion elements that contain a gelator (D) exhibit limited fluidity due to the presence of the gelator (D) when compared with optical wavelength conversion elements that contain no gelator (D), and therefore are not likely to leak out when used in solar cells, photocatalysts, photocatalytic hydrogen and oxygen generating devices, photon upconversion filters, and like articles.

The optical wavelength conversion element in accordance with the present invention further containing the gelator (D) is preferably in a gel state. Due to this property, the optical wavelength conversion element is less likely to leak out when used in solar cells, photocatalysts, photocatalytic hydrogen and oxygen generating devices, photon upconversion filters, and like articles.

The gelator (D) may be any material that dissolves in the ionic liquid (C) to form a gel that exhibits such optical transparency that the gel does not disrupt the light absorption by the organic photosensitizing molecules (A) and the light emission by the organic light-emitting molecules (B). The gelator (D) is preferably an ionic gelator or a nonionic polymer because these agent and polymer can form a gel that exhibits sufficient optical transparency. More preferably, the gelator (D) is an ionic gelator because a small amount of the agent can readily form a gel.

The ionic gelator is preferably a compound of the following general formula

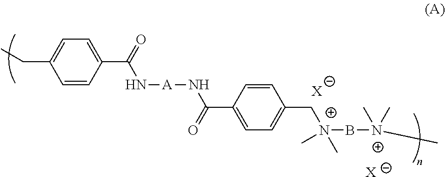

where A is a divalent or cyclohexanediyl group with one or more aromatic rings that may contain a substituent, B is a C₁-C₁₀ alkylene group that may contain a substituent, X⁻ is a monovalent anion, and n is a positive integer in each molecule and is from 1 to 800 when averaged for all molecules.

The cyclohexanediyl group is, for example, a cyclohexane-1,4-diyl group. B in general formula (A) is preferably a C₁-C₆ alkylene group that may contain a substituent and more preferably a C₂-C₆ alkylene group that may contain a substituent. Examples of the substituent that may be contained in the alkylene group include a C₁-C₆ alkyl group, such as a methyl group, an ethyl group, and a propyl group; and a C₁-C₆ alkoxy group, such as a methoxy group, an ethoxy group, and a propoxy group. Specific examples of B in general formula (A) include a methylene group, an ethane-1,2-diyl group, a propane-1,4-diyl group, a butane-1,4-diyl group, a hexane-1,6-diyl group, and a 2-butene-1,4-diyl group.

X⁻ in general formula (A) is by no means limited and may be, for example, a halide ion (F⁻, Cl⁻, Br⁻, or I⁻), a bis(trifluoromethane sulfonyl)amide ion, a bis(fluorosulfonyl)amide ion, a tetrafluoroborate ion (BF₄⁻), a hexafluorophosphate ion (PF₆⁻), a thiocyanate ion (SCN⁻), a nitrate ion (NO₃⁻), a methosulfate ion (CH₃OSO₃⁻), a hydrogencarbonate ion (HCO₃⁻), a hypophosphite ion (H₂PO₂⁻), an oxo-acid ion of a halogen (YO₄⁻, YO₃⁻, YO₂⁻, or YO⁻, where Y is Cl, Br, or I), a tris(trifluoromethane sulfonyl) carbonate ion, a trifluoromethanesulfonate ion, a dicyanamide ion, an acetate ion (CH₃COO⁻), a halogenated acetate ion ((CZₙH₃₋ₙ)COO⁻, where Z is F, Cl, Br, or I, and n is 1, 2, or 3), or a tetraphenylborate ion (BPh₄⁻) or a derivative thereof (B (Aryl)₄⁻, where Aryl is a substituted phenyl group). X⁻ in general formula (A) is preferably a bis(trifluoromethane sulfonyl)amide ion, a bis(fluorosulfonyl)amide ion, or a tetrafluoroborate ion (BF₄⁻).

Preferred examples of the compound of general formula (A) include compounds of the following general formulae

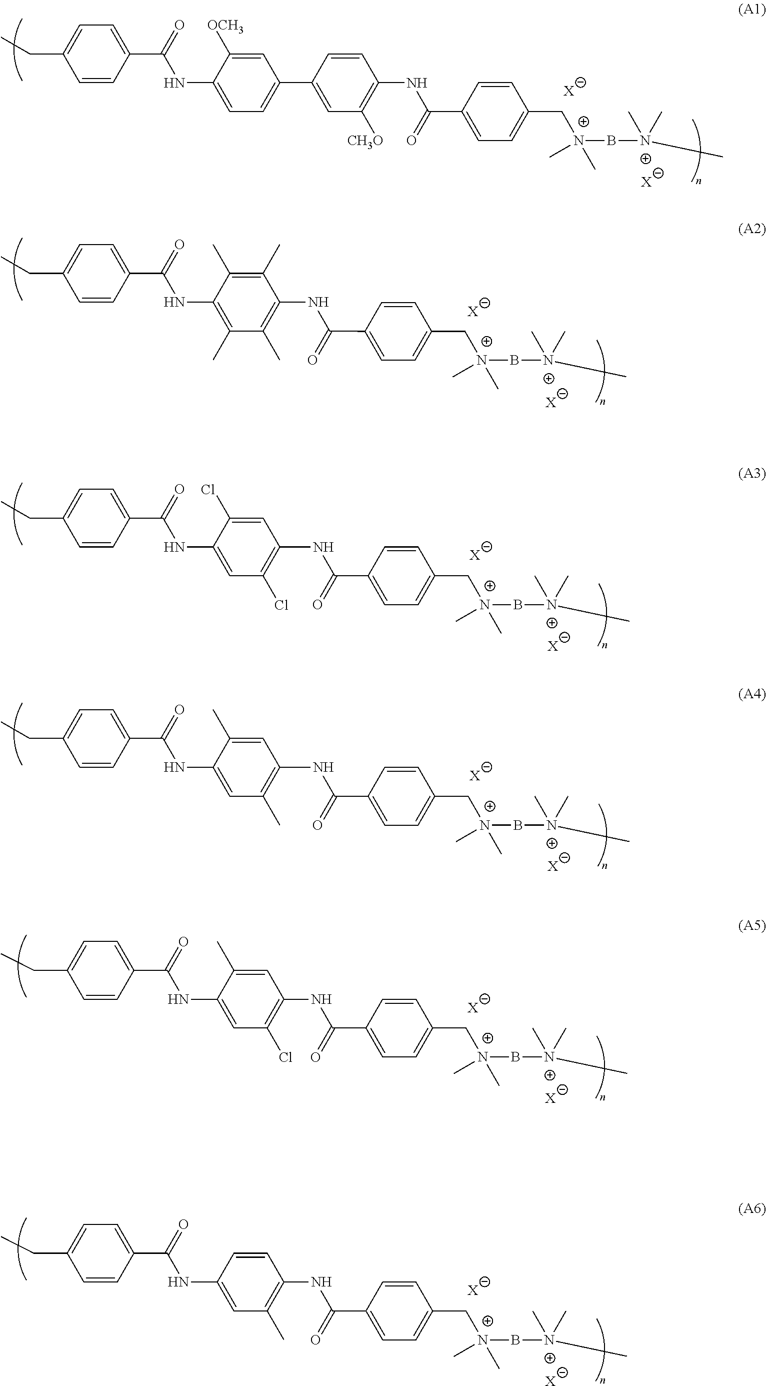

where B is an ethylene group, a 1,3-propylene group, a 1,4-butylene group, or a 1,6-hexylene group, X⁻ is at least one species selected from a halide ion (F⁻, Cl⁻, Br⁻, or I⁻), a bis(trifluoromethane sulfonyl)amide ion, a bis(fluorosulfonyl)amide ion, a tetrafluoroborate ion (BF₄⁻), a hexafluorophosphate ion (PF₆⁻), a thiocyanate ion (SCN⁻), a nitrate ion (NO₃⁻), a methosulfate ion (CH₃OSO₃⁻), a hydrogencarbonate ion (HCO₃⁻), a hypophosphite ion (H₂PO₂⁻), an oxo-acid ion of a halogen (YO₄⁻, YO₃⁻, YO₂⁻, or YO⁻, where Y is Cl, Br, or I), a tris(trifluoromethane sulfonyl) carbonate ion, a trifluoromethanesulfonate ion, a dicyanamide ion, an acetate ion (CH₃COO⁻), a halogenated acetate ion ((CZₙH₃₋ₙ)COO⁻, where Z is F, Cl, Br, or I, and n is 1, 2, or 3), or a tetraphenylborate ion (BPh₄⁻) or a derivative thereof (B (Aryl)₄⁻, where Aryl is a substituted phenyl group), and n is a positive integer in each molecule and is from 1 to 800 when averaged for all molecules,

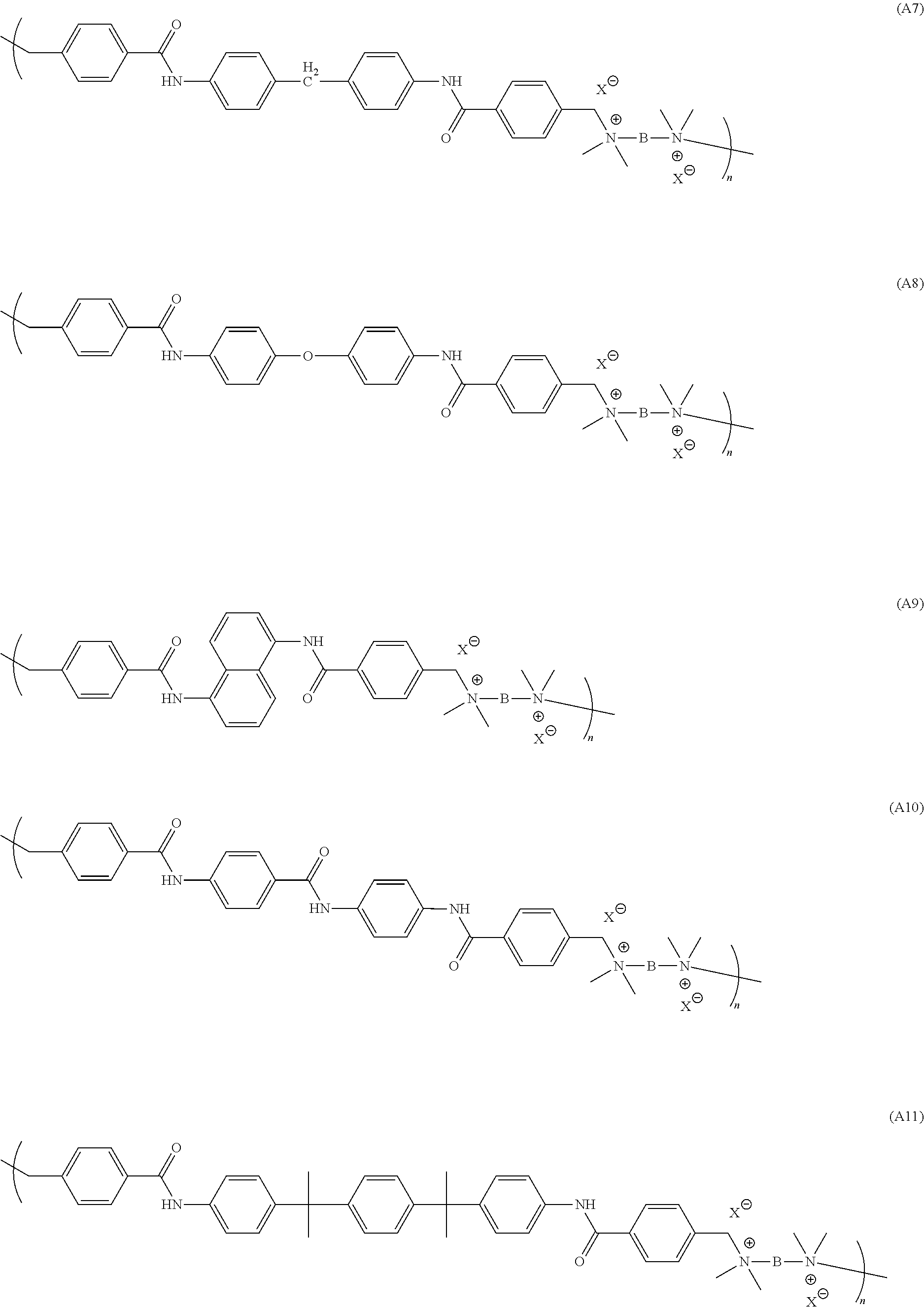

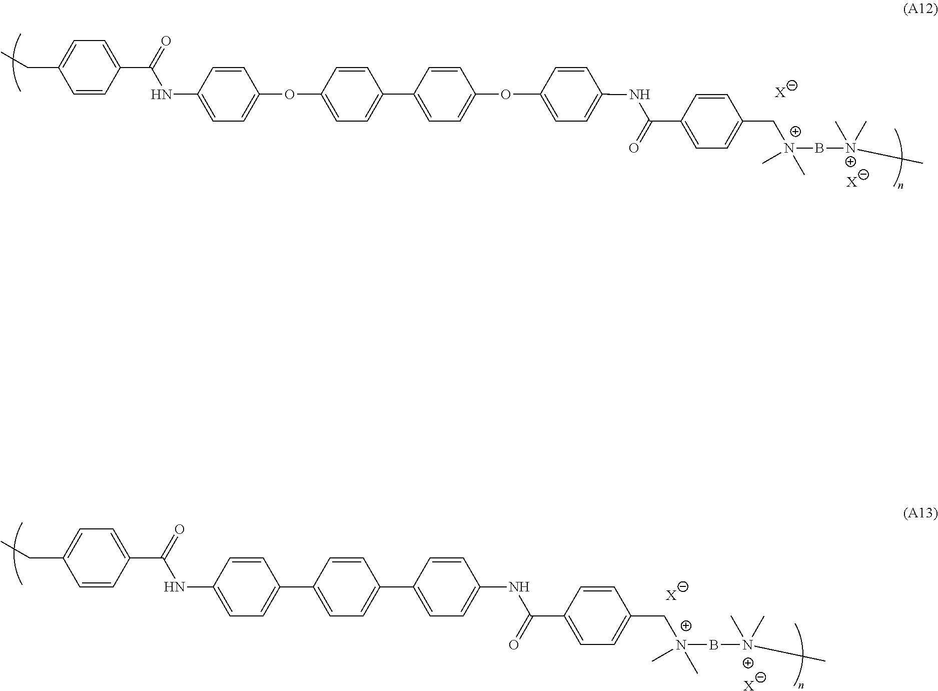

where B is the same as B in formulae (A1) to (A6), and

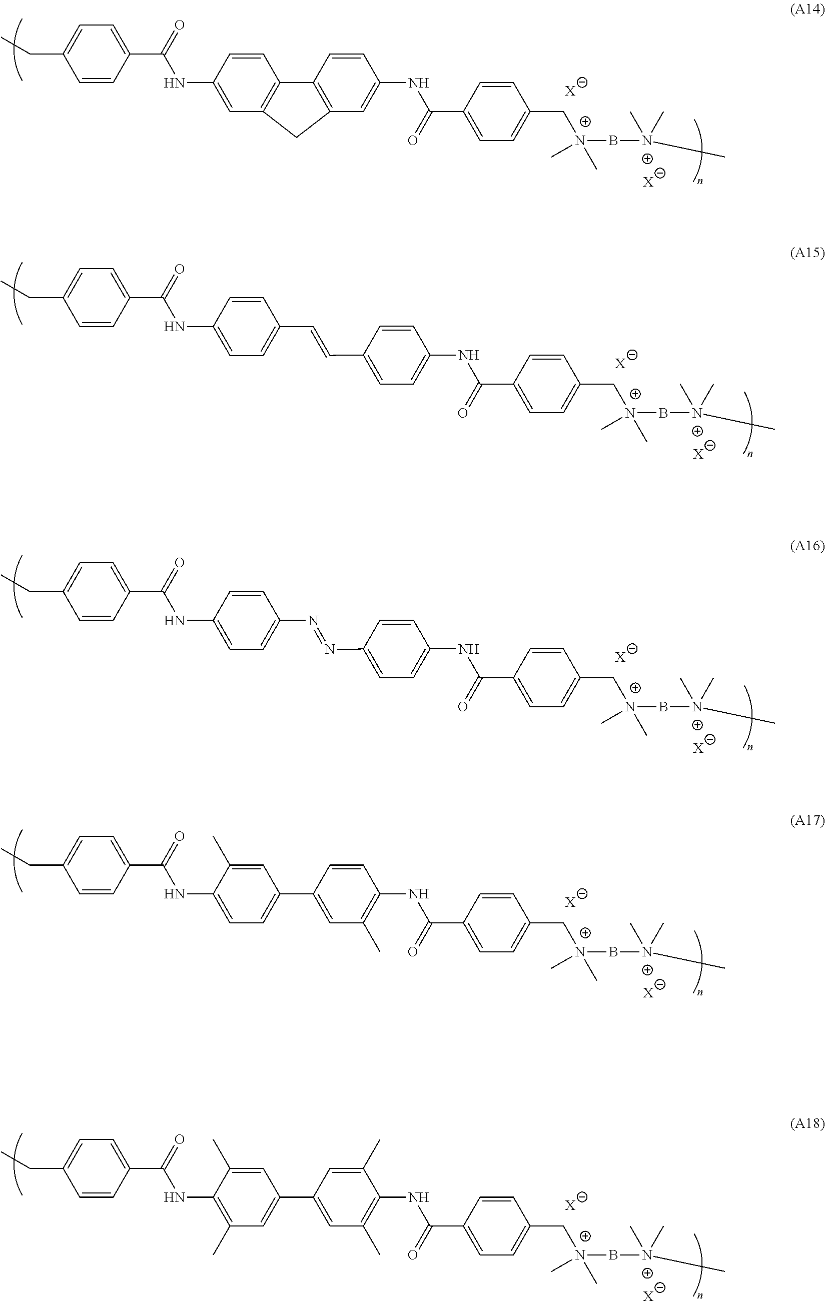

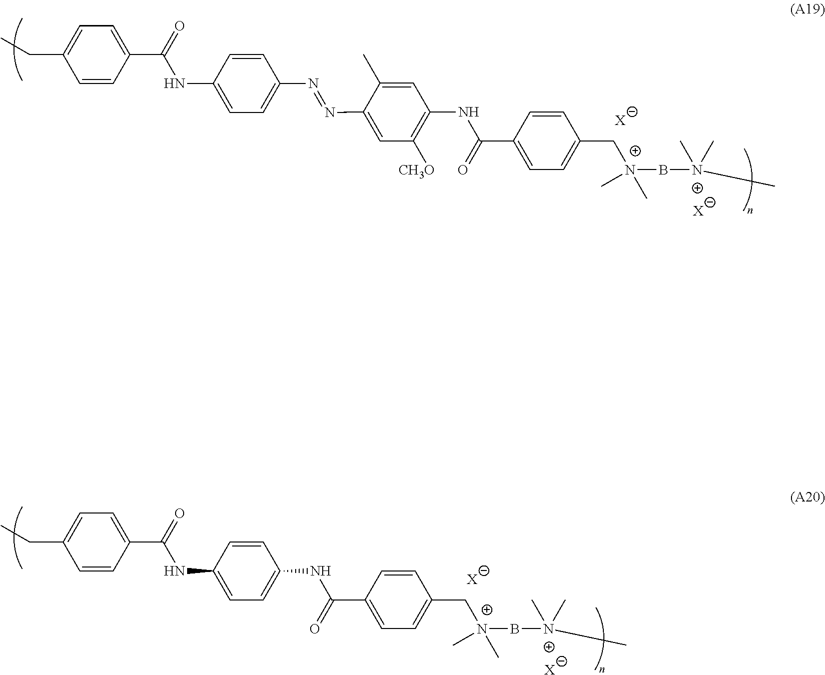

where B is the same as B in formulae (A1) to (A6).

The ionic gelator in the optical wavelength conversion element in accordance with the present invention has a concentration of typically from 0.3 g/L to 100 g/L, preferably from 0.5 g/L to 60 g/L, and more preferably from 1 g/L to 20 g/L. The concentration may however vary depending on the value of n of the ionic gelator and other factors. If the ionic gelator has a concentration of less than 0.3 g/L, the optical wavelength conversion element may not gelate sufficiently. If the ionic gelator has a concentration larger than 100 g/L, the ionic gelator may form a gel with low optical transparency when dissolved in the ionic liquid (C), which may degrade the light wavelength conversion characteristics of the optical wavelength conversion element.

The nonionic polymer may be at least a single polymer of a compound that is capable of forming a nonionic polymer through a polymerization reaction that will be described later in detail. The nonionic polymer preferably has low absorbance.

If the gelator (D) is ionic, the optical wavelength conversion element in accordance with the present invention containing the gelator (D) may be produced, for example, by one of the following two methods. (1) The organic photosensitizing molecules (A) and the organic light-emitting molecules (B) are dissolved and/or dispersed in the ionic liquid (C) to obtain a solution and/or dispersion liquid that are/is mixed with a mixture (solution or gel) of the ionic gelator and the ionic liquid (C). (2) The organic photosensitizing molecules (A) and the organic light-emitting molecules (B) are dissolved and/or dispersed in the ionic liquid (C) to obtain a solution and/or dispersion liquid that are/is mixed with a solution prepared by dissolving the ionic gelator in an organic solvent. Thereafter, the organic solvent is distilled off. Method (1) is preferred to method (2) because method (1) effectively prevents an organic solvent from remaining in the optical wavelength conversion element, thereby delivering the optical wavelength conversion element in a firmer gel state.

The solution and/or dispersion liquid obtained by dissolving and/or dispersing the organic photosensitizing molecules (A) and the organic light-emitting molecules (B) in the ionic liquid (C) may be produced, for example, by dissolving the organic photosensitizing molecules (A) in a volatile organic solvent to prepare a solution of the organic photosensitizing molecules (A), dissolving the organic light-emitting molecules (B) in a volatile organic solvent to prepare a solution of the organic light-emitting molecules (B), and mixing and stirring the solution of the organic photosensitizing molecules (A), the solution of the organic light-emitting molecules (B), and the ionic liquid (C) to form a uniform mixture.

The mixture of the ionic gelator and the ionic liquid (C) may be produced, for example, by dissolving and/or dispersing the ionic gelator in a volatile organic solvent to obtain a mixture, mixing the mixture with the ionic liquid (C), and heating the resultant mixture under reduced pressure to distill off the volatile organic solvent. Another method is to mix and heat the ionic gelator and the ionic liquid (C). Of these two exemplary methods, the former is preferred to the latter because the former is capable of producing a solution or gel by mixing the ionic gelator with the ionic liquid (C) while heating at a relatively low temperature (e.g., 90° C. or lower) and thereby reducing thermally caused coloring and other forms of degradation of the mixture, whereas the latter often requires heating at a relatively high temperature (e.g., 140° C. or higher).

The volatile organic solvent used in the production of the mixture of the ionic gelator and the ionic liquid (C) may be any organic solvent that dissolves and/or disperses the ionic gelator, mixes well with the ionic liquid (C) to form a homogeneous and transparent mixture, and has such volatility that the organic solvent can be removed under reduced pressure until practically a trace amount of the organic solvent is left. A “trace amount” of the volatile organic solvent being left, throughout this specification, means that the volatile organic solvent in the ionic liquid (C) does not stand out above noise levels and is hardly detectable in absorption spectrum measurement. The volatile organic solvent is preferably capable of dissolving the ionic gelator. Examples of the volatile organic solvent include methanol and other alcohol-based solvents.

If the gelator (D) is a nonionic polymer, the optical wavelength conversion element in accordance with the present invention containing the gelator (D) may be produced, for example, by one of the following two methods. (I) The organic photosensitizing molecules (A) and the organic light-emitting molecules (B) are dissolved and/or dispersed in the volatile organic solvent and the ionic liquid (C) to obtain a mixed solution and/or dispersion liquid with which the nonionic polymer is impregnated. The volatile organic solvent is then removed under reduced pressure. (II) The organic photosensitizing molecules (A) and the organic light-emitting molecules (B) are dissolved and/or dispersed in the ionic liquid (C) to obtain a solution and/or dispersion liquid. A compound capable of forming a nonionic polymer through a polymerization reaction (hereinafter referred to as a “polymerizable compound” and will be described later in detail) is mixed with the solution and/or dispersion liquid. The polymerizable compound is then subjected to a polymerization reaction to form the nonionic polymer.

The solution and/or dispersion liquid obtained by dissolving and/or dispersing the organic photosensitizing molecules (A) and the organic light-emitting molecules (B) in the volatile organic solvent and the ionic liquid (C) may be produced, for example, by dissolving the organic photosensitizing molecules (A) in the volatile organic solvent to prepare a solution of the organic photosensitizing molecules (A), dissolving the organic light-emitting molecules (B) in the volatile organic solvent to also prepare a solution of the organic light-emitting molecules (B), and mixing and stirring the solution of the organic photosensitizing molecules (A), the solution of the organic light-emitting molecules (B), and the ionic liquid (C) to obtain a uniform mixture. The solution of the organic photosensitizing molecules (A), the solution of the organic light-emitting molecules (B), and the ionic liquid (C) may be mixed in any order. As an example, the solution of the organic light-emitting molecules (B) may be mixed with the ionic liquid (C) before the solution of the organic photosensitizing molecules (A) may be mixed with the solution of the organic light-emitting molecules (B).

In the “mixed solution and/or dispersion liquid” in method (I), the organic photosensitizing molecules (A) and the organic light-emitting molecules (B) may be dissolved and/or dispersed in only either one of the volatile organic solvent and the ionic liquid (C). Alternatively, the organic photosensitizing molecules (A) and the organic light-emitting molecules (B) may be dissolved and/or dispersed in both the volatile organic solvent and the ionic liquid (C) at a given ratio.

The solution and/or dispersion liquid obtained for use in methods (1), (2), and (II) by dissolving and/or dispersing the organic photosensitizing molecules (A) and the organic light-emitting molecules (B) in the ionic liquid (C) may be produced by dissolving and/or dispersing the organic photosensitizing molecules (A) and the organic light-emitting molecules (B) in the ionic liquid (C) by a conventional, publicly known technique. In these methods, the solution and/or dispersion liquid may be obtained by mixing various additives with the organic photosensitizing molecules (A) and the organic light-emitting molecules (B) in the ionic liquid (C) by a conventional, publicly known technique where necessary. Also in the same methods, the solution and/or dispersion liquid may be obtained by grinding the organic photosensitizing molecules (A) and the organic light-emitting molecules (B) to fine particles in a single publicly known disperser, such as an ultrasonic disperser, a bead mill, a homogenizer, a wet jet mill, a ball mill, an attritor, a sand mill, a roll mill, or a microwave disperser, or any combination of these dispersers, in order to achieve fine dispersion, where necessary.

Alternatively, the solution and/or dispersion liquid obtained for use in methods (1), (2), and (II) by dissolving and/or dispersing the organic photosensitizing molecules (A) and the organic light-emitting molecules (B) in the ionic liquid (C) may be produced by the following, second method as an example. First, the organic photosensitizing molecules (A) and the organic light-emitting molecules (B) are dissolved and/or dispersed in a volatile organic solvent. Next, the obtained solution and/or dispersion fluid is mixed with the ionic liquid (C) while stirring, to obtain a visually homogeneous and transparent solution and/or dispersion fluid. Then, the volatile organic solvent is removed from the solution and/or dispersion fluid under reduced pressure until only a trace amount of the volatile organic solvent is left. This second method is preferred as a method to prepare the solution or dispersion liquid obtained by dissolving and/or dispersing the organic photosensitizing molecules (A) and the organic light-emitting molecules (B) in the ionic liquid (C) because the method readily provides an optical wavelength conversion element in a homogeneous and transparent mixed state and imparts a high stability and high optical wavelength conversion efficiency to the optical wavelength conversion element.

The volatile organic solvent for use in method (I) and the second method may be any organic solvent that dissolves and/or disperses the organic photosensitizing molecules (A) and the organic light-emitting molecules (B), mixes well with the ionic liquid (C) to form a homogeneous and transparent mixture, and has such volatility that the organic solvent can be removed under reduced pressure until practically a trace amount of the organic solvent is left. A “trace amount” of the volatile organic solvent being left, throughout this specification, means that the volatile organic solvent in the ionic liquid (C) does not stand out above noise levels and is hardly detectable in absorption spectrum measurement. The volatile organic solvent is preferably capable of dissolving the organic photosensitizing molecules (A) and the organic light-emitting molecules (B). Examples of the volatile organic solvent include toluene, benzene, xylene, and like aromatic solvents. If a volatile organic solvent is to be used that is capable of dissolving the organic photosensitizing molecules (A) and the organic light-emitting molecules (B), a suitable volatile organic solvent may be selected that suits the solubility of the organic photosensitizing molecules and the organic light-emitting molecules.

The mixing and stirring in method (I) and the second method may involve the use of a publicly known technique or device, such as ultrasound, bubbling, a stirrer, a liquid delivery pump, a pulverizer, a bead mill, a homogenizer, a wet jet mill, or microwave. Any one of these techniques and devices may be used alone; alternatively, two or more of the techniques and devices may be used in any combination.

Generally, the gelator (D) is used in larger amounts to achieve sufficient gelation if a nonionic gelator is used in the optical wavelength conversion element in accordance with the present invention than if an ionic gelator is used. The amount of the ionic liquid (C) contained in every 100 parts by mass of the optical wavelength conversion element is typically 10 parts by mass or more and preferably 30 parts by mass or more.

The nonionic polymer for use in method (I), by no means limited in any particular manner, is preferably a nonionic acrylic resin for high absorption and swellability thereof for the solution or dispersion liquid obtained by dissolving and/or dispersing the organic photosensitizing molecules (A) and the organic light-emitting molecules (B) in the ionic liquid (C). The nonionic acrylic resin is a polymer of a nonionic monomer composed primarily of a (meth)acrylate ((meth)acrylic acid ester), such as methyl methacrylate, methyl acrylate, butyl acrylate, or hydroxyethyl methacrylate. Throughout this specification, “(meth)acrylate” refers to “acrylate” and/or “methacrylate,” whilst “(meth)acrylic” refers to “acrylic” and/or “methacrylic.” The nonionic polymer for use in method (I) may be of any shape and may be shaped like a thin film.

The polymerizable compound for use in method (II) may be a compound capable of forming a nonionic polymer through a thermal polymerization reaction or a compound capable of forming a nonionic polymer through a photopolymerization reaction.

Examples of the compound capable of forming a nonionic polymer through a thermal polymerization reaction include nonionic (meth)acrylic acid esters, such as methyl methacrylate, methyl acrylate, butyl acrylate, and hydroxyethyl methacrylate; nonionic (meth)acrylonitriles, such as acrylonitrile and methacrylonitrile; nonionic styrene compounds, such as styrene, α-methylstyrene, p-methoxystyrene, and p-cyanostyrene; nonionic vinyl carboxylates, such as vinyl acetate; nonionic chlorine-containing monomers, such as vinyl chloride and vinylidene chloride; nonionic (meth)acrylamides, such as acrylamide; nonionic fluorine-containing monomers, such as tetrafluoroethylene; nonionic vinyl ketones, such as methylvinyl ketone; olefins, such as ethylene; and other monomers. Any one of these compounds may be used alone; alternatively, two or more of the compounds may be used in the form of mixture. “(Meth)acrylonitrile,” throughout this specification, refers to “acrylonitrile” and/or “methacrylonitrile.”

To form a nonionic polymer using any of these compounds capable of forming a nonionic polymer through a thermal polymerization reaction, the compound(s) may be subjected to a thermal polymerization reaction after adding, for example, an azo compound, an organic peroxide, or a like radical thermal polymerization initiator to the compound(s).

Other examples of the compound capable of forming a nonionic polymer through a thermal polymerization reaction include epoxy resins. Examples of the epoxy resins include epoxy resins with aliphatic cyclic structures, bisphenol-A epoxy resins, and aromatic polyfunctional epoxy resins with three or more intramolecular epoxy groups. To form a nonionic polymer using any of these epoxy resins, the epoxy resin(s) may be thermally cured by using, for example, an acid anhydride, an acid anhydride derivative, an imidazole, or a like basic curing agent. This method delivers nonionic polymers that show little coloring after curing.

Examples of the compound capable of forming a nonionic polymer through a photopolymerization reaction include monomers containing a polymerizable group, such as a vinyl group, a vinyl ether group, an allyl group, a maleimide group, or a (meth)acryloyl group. Preferred among these examples are monomers containing a (meth)acryloyl group for better reactivity thereof. Examples of the monomers containing a (meth)acryloyl group include (meth)acrylate monomers, such as monofunctional (meth)acrylate monomers having a structure that contains a single (meth)acryloyl group, difunctional (meth)acrylate monomers having a structure that contains two (meth)acryloyl groups, and trifunctional and polyfunctional (meth)acrylate monomers having a structure that contains three or more acryloyl groups. “(Meth)acryloyl,” throughout this specification, refers to “acryloyl” and/or “methacryloyl.”

Examples of the monofunctional (meth)acrylate monomers include phenoxyethyl (meth)acrylate, phenyl(poly)ethoxy (meth)acrylate, p-cumylphenoxyethyl (meth)acrylate, tribromophenyloxyethyl (meth)acrylate, phenylthioethyl (meth)acrylate, 2-hydroxy-3-phenyloxypropyl (meth)acrylate, phenylphenol(poly)ethoxy (meth)acrylate, phenylphenol epoxy (meth)acrylate, acryloylmorpholine, 2-hydroxypropyl (meth)acrylate, 4-hydroxybutyl (meth)acrylate, cyclohexane-1,4-dimethanol mono(meth)acrylate, tetrahydrofurfuryl (meth)acrylate, isobornyl (meth)acrylate, dicyclopentanyl (meth)acrylate, dicyclopentenyl (meth)acrylate, and dicyclopentenyloxyethyl (meth)acrylate. “(Poly)ethoxy,” throughout this specification, refers to “ethoxy” and/or “polyethoxy.”

Examples of the difunctional (meth)acrylate monomers include 1,4-butanediol di(meth)acrylate, 1,6-hexanediol di(meth)acrylate, 1,9-nonanediol di(meth)acrylate, tricyclodecane dimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, polyethylene glycol di(meth)acrylate, and a di(meth)acrylate of ε-caprolactone adduct of neopentyl glycol hydroxypivalate (e.g., KAYARAD® HX-220 and KAYARAD® HX-620 manufactured by Nippon Kayaku Co., Ltd.).

Examples of the trifunctional and polyfunctional (meth)acrylate monomers include tris(acryloxyethyl) isocyanurate, pentaerythritol tetra(meth)acrylate, dipentaerythritol hexa(meth)acrylate, dipentaerythritol penta(meth)acrylate, tripentaerythritol hexa(meth)acrylate, tripentaerythritol penta(meth)acrylate, trimethylolpropane tri(meth)acrylate, trimethylolpropane polyethoxy tri(meth)acrylate, and ditrimethylolpropane tetra(meth)acrylate.

Examples of the monomers containing a (meth)acryloyl group include (meth)acrylate oligomers, such as urethane (meth)acrylate, epoxy (meth)acrylate, and polyester (meth)acrylate. Any one of these examples may be used alone; alternatively, two or more of the examples may be used in the form of mixture.

To form a nonionic polymer using the compound capable of forming a nonionic polymer through a photopolymerization reaction, at least one of photopolymerization initiators (e.g., benzoins, acetophenones, anthraquinones, thioxanthones, ketals, benzophenones, and phosphine oxides) is added to the compound capable of forming a nonionic polymer through a photopolymerization reaction to obtain a mixture that is irradiated with ultraviolet light for a photopolymerization reaction of the compound.

The optical wavelength conversion element in accordance with the present invention has a water content of preferably 1 mass % or less, more preferably 0.1 mass % or less, even more preferably 0.01 mass % or less, and most preferably 0.001 mass % or less. The resultant optical wavelength conversion element has a further improved optical wavelength conversion efficiency.

The optical wavelength conversion element in accordance with the present invention has an oxygen concentration of preferably 100 mass ppm or less, more preferably 10 mass ppm or less, even more preferably 1 mass ppm or less, and most preferably 0.1 mass ppm or less. The resultant optical wavelength conversion element has a further improved optical wavelength conversion efficiency.

The optical wavelength conversion element in accordance with the present invention is a visually homogeneous and transparent solution and/or dispersion fluid and has a good stability. The optical wavelength conversion element in accordance with the present invention is applicable to solar cells, photocatalysts, photocatalytic hydrogen and oxygen generating devices, photon upconversion filters, and like articles.

A solar cell in accordance with the present invention contains therein the optical wavelength conversion element in accordance with the present invention.

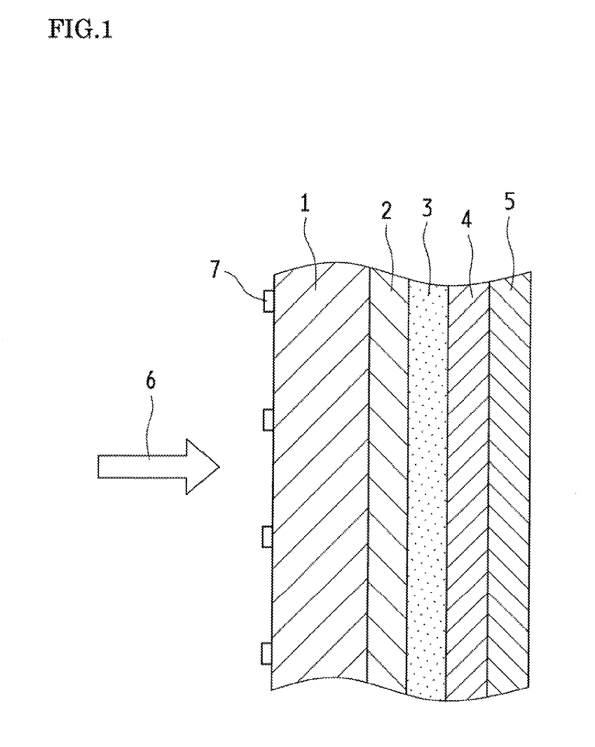

An exemplary solar cell in accordance with the present invention will be described in reference to FIG. 1. A solar cell in accordance with an example of the present invention, as illustrated in FIG. 1, includes a photoelectric conversion layer (photovoltaic layer) 1, strips of light-receiving face electrodes 7 disposed on a light-incident face of the photoelectric conversion layer 1, a transparent back-face electrode 2 stacked on a back face of the photoelectric conversion layer 1 (opposite from the light-incident face of the photoelectric conversion layer 1), a transparent insulating film 3 stacked on a back face of the transparent back-face electrode 2 (opposite from a light-incident face of the transparent back-face electrode 2), an upconversion layer 4 containing the optical wavelength conversion element in accordance with the present invention and stacked on a back face of the transparent insulating film 3 (opposite from a light-incident face of the transparent insulating film 3), and a light reflecting film 5 stacked on a back face of the upconversion layer 4 (opposite from a light-incident face of the upconversion layer 4).

The photoelectric conversion layer 1, by no means limited in any particular manner, may be an organic photoelectric conversion layer used in, for example, dye-sensitized solar cells and organic thin film solar cells, a compound semiconductor-based photoelectric conversion layer, or a silicon-based photoelectric conversion layer.

The light-receiving face electrodes 7 and the light reflecting film 5 may be composed of a metal, such as Ag, Al, Ti, Cr, Mo, W, Ni, or Cu. The transparent back-face electrode 2 may be composed of a transparent conductor, such as ITO (indium tin oxide), SnO₂, or ZnO. The transparent insulating film 3 may be composed of a resin, such as polyethylene terephthalate, a polycarbonate, a polyimide resin, an acrylic resin, or a polyether nitrile.

The upconversion layer 4 may be formed of either a cell and an optical wavelength conversion element sealed in the cell similarly to a photon upconversion filter in accordance with the present invention (details will be given later) or an optical wavelength conversion element alone. If the upconversion layer 4 is formed of an optical wavelength conversion element alone, the transparent insulating film 3, the upconversion layer 4, and the light reflecting film 5 may be sealed with a sealing member (e.g., sealing resin) along the periphery thereof.

According to the arrangement in FIG. 1, the upconversion layer 4 upconverts (converts light of relatively long wavelengths to light of relatively short wavelengths) incident light 6 from the sun. This upconversion increases the intensity of light in the range of wavelengths that can be exploited by the photoelectric conversion layer 1 for electric power generation, which in turn further improves the electric power generation efficiency of the solar cell.

The arrangement in FIG. 1 shows the upconversion layer 4 being located between the transparent insulating film 3 and the light reflecting film 5. The upconversion layer 4 may, however, be disposed in a different location, for example, on light-incident faces of the light-receiving face electrodes 7, in which case there may be provided a transparent insulating film between the upconversion layer 4 and the light-receiving face electrodes 7.

In the solar cell in FIG. 1, the light-receiving face electrodes 7 may be replaced by transparent electrodes formed across the entire light-incident face of the photoelectric conversion layer 1. In addition, the transparent insulating film 3 may be omitted in the solar cell in FIG. 1. If the upconversion layer 4 is formed of an optical wavelength conversion element alone, the transparent insulating film 3 is preferably disposed between the optical wavelength conversion element and the transparent back-face electrode 2 to prevent contacts between the optical wavelength conversion element and the transparent back-face electrode 2. Furthermore, in the solar cell in FIG. 1, if the upconversion layer 4 is relocated to the light-incident faces of the light-receiving face electrodes 7, and the transparent insulating film 3 is omitted, the transparent back-face electrode 2 may be replaced by a light reflecting electrode to omit the light reflecting film 5.

A photocatalyst in accordance with the present invention contains therein the optical wavelength conversion element in accordance with the present invention. For example, a photocatalytic layer may be disposed in the solar cell in FIG. 1, replacing the light-receiving face electrodes 7, the photoelectric conversion layer 1, the transparent back-face electrode 2, and the transparent insulating film 3, to obtain a photocatalyst with high catalytic efficiency.

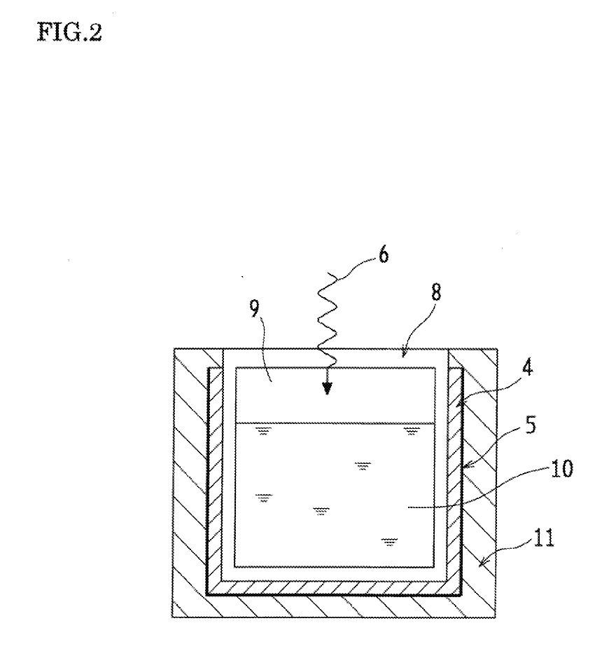

A photocatalyst in accordance with an example of the present invention, as illustrated in FIG. 2, includes a glass channel 8, an upconversion layer 4, a light reflecting film 5, and a mechanical support 11. The glass channel 8 contains water 10 to which the photocatalyst has been added (photocatalytic layer) and has a remaining space thereof (where there is no water 10) filled with a gas 9. The upconversion layer 4 is formed on the side and bottom faces of the glass channel 8. The light reflecting film 5 is formed on the exterior faces of the upconversion layer 4. The mechanical support 11 is formed on the exterior faces of the light reflecting film 5 to support the light reflecting film 5.

According to the arrangement in FIG. 2, the upconversion layer 4 upconverts (converts light of relatively long wavelengths to light of relatively short wavelengths) incident light 6 from the sun. This upconversion increases the intensity of light in the range of wavelengths that can be exploited by the photocatalyst added to the water 10 for a catalytic reaction, which in turn further improves photocatalytic conversion efficiency.

A photocatalytic hydrogen and oxygen generating device in accordance with the present invention contains therein the optical wavelength conversion element in accordance with the present invention. For example, a photocatalytic layer may be disposed in the solar cell in FIG. 1, replacing the light-receiving face electrodes 7, the photoelectric conversion layer 1, the transparent back-face electrode 2, and the transparent insulating film 3, to obtain a photocatalytic hydrogen and oxygen generating device with a high hydrogen and oxygen generating efficiency.

A photon upconversion filter in accordance with the present invention converts light of relatively long wavelengths to light of relatively short wavelengths and includes the optical wavelength conversion element in accordance with the present invention and a cell.

The cell may be any cell that is transparent to light and may be fabricated, for example, by placing two plates of glass (e.g., quartz glass or borosilicate glass), one on top of the other, and fusion-joining the peripheries of the plates.

The optical wavelength conversion element as sealed in the cell has an oxygen concentration of preferably 100 mass ppm or less, more preferably 10 mass ppm or less, even more preferably 1 mass ppm or less, and most preferably 0.1 mass ppm or less. If the optical wavelength conversion element has an oxygen concentration of 100 mass ppm or less as it is sealed in the cell, the oxygen concentration is maintained at low values. The resultant photon upconversion filter stably exhibits such a high optical wavelength conversion efficiency that the filter is viable even under sunlight or similar, low intensity light.

The photon upconversion filter may be obtained, for example, by injecting the optical wavelength conversion element into the cell, deoxidizing the element as necessary to lower oxygen concentration in the element to 100 mass ppm or less, and sealing the cell. The deoxidation may be done by one of the following three methods. (1) The optical wavelength conversion element is processed under reduced pressure using, for example, a vacuum pump, such as a rotary pump or a turbomolecular pump. (2) The optical wavelength conversion element is bubbled with an inert gas, such as nitrogen gas or argon gas. (3) The optical wavelength conversion element is frozen and thereafter processed under reduced pressure using a vacuum pump (vacuum deaeration, freeze vacuum degassing).

This photon upconversion filter may be used as the upconversion layer 4 in the aforementioned solar cell, photocatalyst, and photocatalytic hydrogen and oxygen generating device.

An oxygen getter may coexist in the solar cells, photocatalysts, photocatalytic hydrogen and oxygen generating devices, photon upconversion filters, and like articles that contain the optical wavelength conversion element in accordance with the present invention, to lower oxygen concentration in the optical wavelength conversion element. In addition, a water absorbing material may coexist in the solar cells, photocatalysts, photocatalytic hydrogen and oxygen generating devices, photon upconversion filters, and like articles that contain the optical wavelength conversion element in accordance with the present invention, to lower oxygen concentration in the optical wavelength conversion element.

### EXAMPLES OF THE INVENTION

Next, the present invention will be described in more detail by way of examples. The present invention is by no means limited by these examples. The ultrapure water used in the following preparation examples of the ionic liquid (C) is described first below.

### Production of Ultrapure Water

The ultrapure water used in the following preparation examples of the ionic liquid (C) was prepared using an ultrapure water producing device (manufactured by Merck KGaA, Product Number: Direct-Q® UV3).

### Synthesis Example 1 of Organic Photosensitizing Molecules (A)

The organic photosensitizing molecules (A) (2-iodo-1,3,5,7-tetramethyl-8-phenyl-4,4-difluoroboradiazaindacene) of

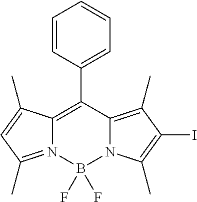

was synthesized by a method described in Non-patent Document 6. The obtained compound was identified by the following NMR spectroscopy.

¹H NMR (400 MHz, CDCl₃): δ 7.51-7.48 (m, 3H), 7.27-7.25 (m, 2H), 6.04 (s, 1H), 2.63 (s, 3H), 2.57 (s, 3H), 1.38 (s, 6H)

¹³C NMR (100 MHz, CDCl₃): δ 157.9, 154.7, 145.3, 143.4, 141.7, 135.0, 132.0, 131.1, 129.8, 129.5, 129.4, 128.0, 122.5, 84.4, 16.8, 16.0, 14.9, 14.7

### Synthesis Example 2 of Organic Photosensitizing Molecules (A)

The organic photosensitizing molecules (A) (2,6-diiodo-1,3,5,7-tetramethyl-8-phenyl-4,4-difluoroboradiazaindacene) of

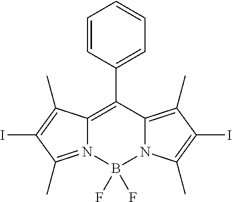

was synthesized by a method described in Non-patent Document 6. The obtained compound was identified by the following NMR spectroscopy.

¹H NMR (400 MHz, CDCl₃): δ 7.54-7.51 (m, 3H), 7.26-7.24 (m, 2H), 2.65 (s, 6H), 1.38 (s, 6H)

¹³C NMR (100 MHz, CDCl₃): δ 156.9, 145.5, 141.5, 134.4, 129.7, 129.6, 127.9, 85.8, 17.1, 16.2

### Preparation Example 1 of Ionic Liquid (C)

A commercial product (manufactured by Ionic Liquids Technologies GmbH) of a water-immiscible ionic liquid, 1-propyl-2,3-dimethylimidazolium bis(trifluoromethylsulfonyl)imide (CAS Number: 169051-76-7; “Ionic Liquid #1”), was taken in a glass vial. To this commercial product of the Ionic Liquid #1 taken in the vial was added a volume of ultrapure water that is 9 times as much as the volume of the commercial product. This mixture was then stirred using a general-purpose magnetic stirrer and a stirring bar and let to stand (the commercial product was washed with a volume of ultrapure water that is 9 times as much as the volume of the commercial product). As a result, the contents of the glass vial separated into a layer of the ionic liquid on the bottom of the glass vial and an aqueous layer atop the layer of the ionic liquid. Thereafter, the aqueous layer was extracted for measurement of the pH thereof (the pH of the water resulting from the washing), which was 3.9.

Meanwhile, 1 mL of the commercial product of the Ionic Liquid #1 was taken in a glass vial (capacity: about 8 mL). Activated charcoal (30 mg) was added to this commercial product of the Ionic Liquid #1, and the resultant mixture was vacuum dried at 140° C. for 3 hours in a vacuum dry oven (manufactured by Yamato Scientific Co., Ltd., Product Number: ADP200). The glass vial was taken out of the vacuum dry oven and subjected to centrifuge separation to obtain a supernatant containing almost no activated charcoal. The obtained supernatant was filtered using a disposable syringe filter with a pore size of about 0.2 μm (manufactured by Merck KGaA, Product Number: IC Millex®-LG) to remove activated charcoal residues, before being poured into a glass vial (capacity: about 20 mL). To the contents of the glass vial was added a volume of ultrapure water that is 9 times as much as the volume of the contents. This mixture was then stirred for 5 minutes using a general-purpose magnetic stirrer and a stirring bar, let to stand for a few minutes, and rid of an aqueous layer. This washing process was repeated 3 times. The pH of the aqueous layer removed in the third washing (pH of the water resulting from the washing) was measured to be 6.5.

Finally, the aqueous layer remaining in the glass vial was removed as much as possible using a glass Pasteur pipette (manufactured by Fisher Scientific Inc., Product Number: 5-5351-01). The contents of the glass vial (ionic liquid layer) was dried at 70° C. overnight in a forced convection dry oven (available from Advantec Toyo Kaisha, Ltd., manufactured by Toyo Engineering Works, Ltd., Product Number: DRM320DB) and thereafter vacuum dried at 120° C. for 3 hours in the same vacuum dry oven as that used in the previous vacuum drying, to obtain the Ionic Liquid #1 (ionic liquid (C)).

### Preparation Example 2 of Ionic Liquid (C)

The same process as the process performed in Preparation Example 1 of the ionic liquid (C) (3 rounds of washing of the ionic liquid with a volume of ultrapure water that is 9 times as much as the volume of the ionic liquid (C) (followed by stirring and removing of an aqueous layer)) was performed, except that a commercial product (manufactured by Ionic Liquids Technologies GmbH) of another water-immiscible ionic liquid, 1-butyl-2,3-dimethylimidazolium bis(trifluoromethylsulfonyl)imide (CAS Number: 350493-08-2; “Ionic Liquid #2”), was used in place of the commercial product of the Ionic Liquid #1 used in Preparation Example 1 of the ionic liquid (C). As a result, the pH of the aqueous layer removed in the third washing (pH of the water resulting from the washing) was 6.4, and the Ionic Liquid #2 (ionic liquid (C)) was obtained.

### Preparation Example 3 of Ionic Liquid (C)

The same process as the processes performed in Preparation Examples 1 and 2 of the ionic liquid (C) was performed to obtain the Ionic Liquid #1 and the Ionic Liquid #2 (ionic liquids (C)). In addition, the same process as the process performed in Preparation Example 1 of the ionic liquid (C) was performed, except that a commercial product (manufactured by Ionic Liquids Technologies GmbH) of another water-immiscible ionic liquid, 1-ethyl-3-methylimidazolium bis(trifluoromethylsulfonyl)imide (CAS Number: 174899-82-2; “Ionic Liquid #3”), a commercial product (manufactured by Ionic Liquids Technologies GmbH) of another water-immiscible ionic liquid, 1-butyl-3-methylimidazolium bis(trifluoromethylsulfonyl)imide (CAS Number: 174899-83-3; “Ionic Liquid #4”), a commercial product (manufactured by Merck KGaA) of another water-immiscible ionic liquid, 1-butyl-3-methylimidazolium bis(trifluoromethylsulfonyl)imide (CAS Number: 174899-83-3; “Ionic Liquid #5”), a commercial product (manufactured by Merck KGaA) of another water-immiscible ionic liquid, ethyl-dimethyl-propylammonium bis(trifluoromethylsulfonyl)imide (CAS Number: 258273-77-7; “Ionic Liquid #6”), a commercial product (manufactured by Merck KGaA) of another water-immiscible ionic liquid, 1-propyl-2,3-dimethylimidazolium bis(trifluoromethylsulfonyl)imide (CAS Number: 169051-76-7; “Ionic Liquid #7”), a commercial product (manufactured by Merck KGaA) of another water-immiscible ionic liquid, 1-ethyl-3-methylimidazolium tris(pentafluoroethyl) trifluorophosphate (CAS Number: 377739-43-0; “Ionic Liquid #8”), a commercial product (manufactured by Merck KGaA) of another water-immiscible ionic liquid, 1-hexyl-3-methylimidazolium tris(pentafluoroethyl) trifluorophosphate (CAS Number: 713512-19-7; “Ionic Liquid #9”), a commercial product (manufactured by Merck KGaA) of another water-immiscible ionic liquid, 1-butyl-1-methylpyrrolidinium bis(trifluoromethylsulfonyl)imide (CAS Number: 223437-11-4; “Ionic Liquid #10”), a commercial product (manufactured by Merck KGaA) of another water-immiscible ionic liquid, 1-butyl-2,3-dimethylimidazolium bis(trifluoromethylsulfonyl)imide (CAS Number: 350493-08-2; “Ionic Liquid #11”), a commercial product (manufactured by Merck KGaA) of another water-immiscible ionic liquid, 1-hexyl-3-methylimidazolium bis(trifluoromethylsulfonyl)imide (CAS Number: 382150-50-7; “Ionic Liquid #12”), a commercial product (manufactured by Merck KGaA) of another water-immiscible ionic liquid, 1-butyl-1-methylpyrrolidinium tris(pentafluoroethyl) trifluorophosphate (CAS Number: 851856-47-8; “Ionic Liquid #13”), and a commercial product (manufactured by Merck KGaA) of another water-immiscible ionic liquid, methyltri-n-octylammonium bis(trifluoromethylsulfonyl)imide (CAS Number: 375395-33-8; “Ionic Liquid #14”) were respectively used in place of the commercial product of the Ionic Liquid #1 used in Preparation Example 1 of the ionic liquid (C), to obtain the Ionic Liquid #3, Ionic Liquid #4, Ionic Liquid #5, Ionic Liquid #6, Ionic Liquid #7, Ionic Liquid #8, Ionic Liquid #9, Ionic Liquid #10, Ionic Liquid #11, Ionic Liquid #12, Ionic Liquid #13, and Ionic Liquid #14 (ionic liquids (C)).

A portion of each Ionic Liquid #1 to #14 obtained as the ionic liquid (C) was set aside, to which a volume of ultrapure water that is 9 times as much as the volume of the ionic liquid (C) was added. Each portion was then stirred for 5 minutes using a general-purpose magnetic stirrer and a stirring bar and let to stand for a few minutes. Thereafter, an aqueous layer was extracted from each portion. The pH's of all the aqueous layers (pH's of the water resulting from the washing) were measured to be larger than 5.

### Checking Dissolution Stability of Organic Photosensitizing Molecules (A) in Ionic Liquid (C)

The following experiment was performed to check that the organic photosensitizing molecules (A) (2,6-diiodo-1,3,5,7-tetramethyl-8-phenyl-4,4-difluoroboradiazaindacene) obtained in Synthesis Example 2 of the organic photosensitizing molecules (A) was capable of dissolving and/or dispersing in the ionic liquid (C) to produce a visually homogeneous and transparent mixture and that this state of dissolution and/or dispersion was stably maintained.

First, three glass vials, each of which has a capacity of about 8 mL were prepared. The Ionic Liquid #1 (300 μL), Ionic Liquid #3 (300 μL), and Ionic Liquid #12 (300 μL) (ionic liquids (C) prepared in advance by the same procedures as in Preparation Example 1 of the ionic liquid (C) so as to produce water with a pH larger than 5 when washed with a volume of ultrapure water that is 9 times as much as the volume of the ionic liquid (C)) were put in respective glass vials.

Subsequently, a 3×10⁻⁴ M toluene solution (100 μL) of the organic photosensitizing molecules (A) (2,6-diiodo-1,3,5,7-tetramethyl-8-phenyl-4,4-difluoroboradiazaindacene) obtained in Synthesis Example 2 of the organic photosensitizing molecules (A) was added to each of the three glass vials. The contents of the glass vials were then thoroughly mixed by repeated suction-and-ejection using a glass Pasteur pipette (manufactured by Fisher Scientific Inc., Product Number: 5-5351-01) until a visually homogeneous and transparent mixed liquid was obtained. The glass vials were then capped and stirred for about 7 minutes in an ultrasonic bath sonicator (manufactured by Branson Ultrasonics Corp., Product Number: Model 3510) for better homogeneousness. The glass vials were then uncapped and set in a vacuum container before being processed under reduced pressure at room temperature for about 8 hours using a scroll pump (manufactured by Edwards, Product Number: XDS35i, Designed Ultimate Pressure is less than 1 Pa). This procedure removed the toluene until only a trace amount thereof was left. A visually homogeneous and transparent, single-layer solution and/or dispersion fluid (liquid) was hence obtained.

Subsequently, to check the stability of these liquids, the three glass vials were let to stand for storage purposes on a shelf in air at room temperature where there was no light. After 162 hours, the vials were removed from the shelf and checked. The liquids remained visually homogeneous and transparent. The three liquids were dispensed dropwise in small amounts, each on a different glass slide, and observed under a microscope with the objective lens magnifications of 10× and 50×. The observation found no crystallite or other solid deposits at all in any of the liquids and confirmed that the organic photosensitizing molecules (A) obtained in Synthesis Example 2 of the organic photosensitizing molecules (A) stably remained dissolved and/or dispersed in the ionic liquid (C) in a visually homogeneous and transparent manner.

### Example 1

### Preparation of Optical Wavelength Conversion Element

The Ionic Liquid #1 (400 μL) obtained as the ionic liquid (C) in Preparation Example 1 of the ionic liquid (C) was put in a glass vial (capacity: about 8 mL) at room temperature. Subsequently, to this Ionic Liquid #1 (ionic liquid (C)) was added a 2×10⁻⁴ M toluene solution (about 20 μL) of meso-tetraphenyl-tetrabenzoporphyrin palladium (CAS Number: 119654-64-7) as the organic photosensitizing molecules (A) and a 4×10⁻³ M toluene solution (about 300 μL) of perylene (CAS Number: 198-55-0) as the organic light-emitting molecules (B). A visually non-homogeneous mixed liquid was hence obtained. This visually non-homogeneous mixed liquid was then thoroughly mixed by repeated suction-and-ejection using the same type of glass Pasteur pipette as that used in Preparation Example 1 of the ionic liquid (C), similarly to a method described in Patent Document 3. A visually homogeneous and transparent mixed liquid was hence obtained. Thereafter, the glass vial was capped and stirred for about 10 minutes in an ultrasonic bath sonicator (manufactured by Branson Ultrasonics Corp., Product Number: Model 3510) for better homogeneousness.

Thereafter, the glass vial was uncapped and set in a vacuum container before being processed under reduced pressure at room temperature for about 8 hours using a scroll pump (manufactured by Edwards, Product Number: XDS35i, Designed Ultimate Pressure is less than 1 Pa). This procedure removed the volatile toluene until only a trace amount thereof was left. A visually homogeneous and transparent, single-layer solution and/or dispersion fluid (liquid) was hence obtained. Furthermore, the glass vial was placed inside a purpose-made, cylindrical, aluminum vacuum chamber (inner dimensions: 10 cm in diameter×6 cm in height) set in a glovebox filled with argon. After being closed hermetically with a special lid, the vacuum chamber was vacuumed overnight using a turbomolecular pump (manufactured by Pfeiffer Vacuum Technology AG Product Number: HiCube 80, Ultimate Pressure: about 10⁻⁴ to 10⁻⁵ Pa) at a degree of vacuum of about 10⁻⁴ to 10⁻⁵ Pa, to thoroughly remove residual molecular oxygen. A visually homogeneous and transparent liquid was hence obtained as an optical wavelength conversion element.

### Evaluation of Emission of Upconverted Light by Optical Wavelength Conversion Element

Subsequently, the lid of the vacuum chamber was opened in the glovebox. Similarly to a method described in Patent Document 3, in the glovebox, a portion of the liquid (optical wavelength conversion element) was injected into a square quartz tube (inner dimensions: 1 mm×1 mm, outer dimensions: 2 mm×2 mm, and length about 25 mm) with one open end to fill about ¾ the full length of the tube. The open end of the quartz tube was sealed using lead soldering. An upconversion emission evaluation sample sealed in the quartz tube was hence obtained. The upconversion emission evaluation sample includes an optical wavelength conversion element and a quartz tube as a cell and is an equivalent of a photon upconversion filter in accordance with the present invention. The optical wavelength conversion element was sealed in the quartz tube at an oxygen concentration of 100 ppm or less.

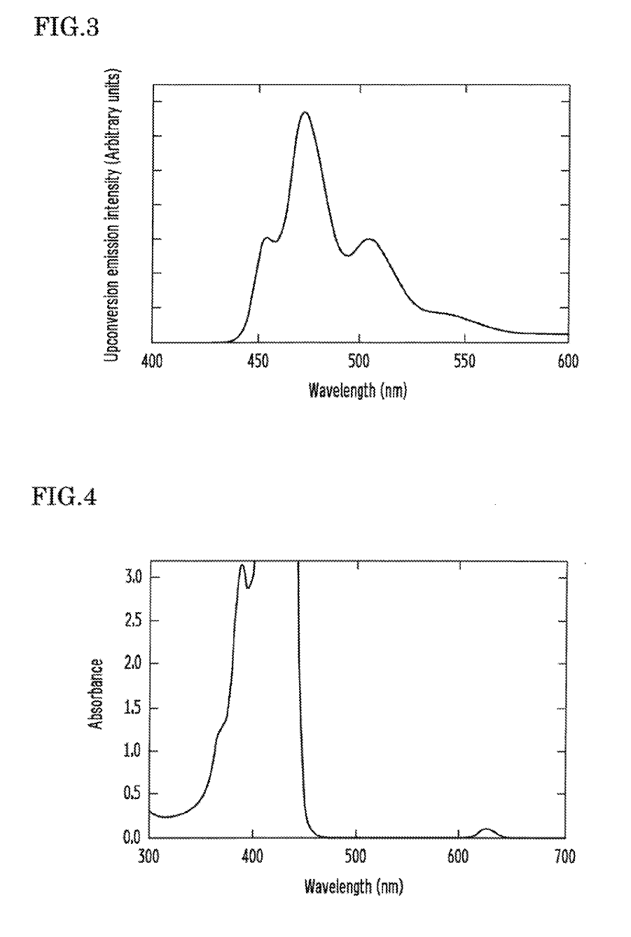

The fabricated upconversion emission evaluation sample was held in a special sample holder. Continuous wave laser light as excitation light (wavelength: 632.8 nm, spot diameter: about 0.8 mm, and output power: about 28 mW, “Continuous Wave Laser Light #1”) was emitted from a continuous wave laser generator (manufactured by CVI Melles Griot Inc., Product Number: 25 LHP 928-249) and shone onto the sample. Bright and blue upconverted light emission (maximum peak near 475 nm) was recognized by eyes. The upconverted light emitted from the same upconversion emission evaluation sample was collected and directed by a converging lens in a direction perpendicular to the incident excitation light and converged by another lens onto an inlet slit of a monochromator (manufactured by Roper Scientific GmbH, Product Number: SP-2300i) The spectrum (spectral profile) and intensity of the upconverted light emission were measured using an electronically cooled silicon CCD detector (manufactured by Roper Scientific GmbH, Product Number: Pixis 100BR) mounted after the monochromator. The upconversion emission spectrum obtained from the measurement is shown in FIG. 3. The intensity of the upconversion emission spectrum was monitored over time. The monitoring revealed that the intensity of the upconverted light emitted from the upconversion emission evaluation sample did not change throughout the time during which Continuous Wave Laser Light #1 was shone (a few minutes), demonstrating that the upconversion emission evaluation sample is highly stable under irradiation with Continuous Wave Laser Light #1.

### Measurement of Absorption Spectrum of Optical Wavelength Conversion Element

The remaining liquid (optical wavelength conversion element), which was not used in the fabrication of the upconversion emission evaluation sample, was placed in a thin-type quartz cell (thickness: 1 mm) to obtain an absorption spectrum measuring sample. The absorption spectrum of the absorption spectrum measuring sample was measured with an ultraviolet/visible/near-infrared light spectrophotometer (manufactured by Shimadzu Corporation, Product Number: UV-3600). The absorption spectrum obtained from the measurement is shown in FIG. 4.

### Comparative Example 1

A visually homogeneous and transparent liquid as a comparative optical wavelength conversion element was prepared by the same procedures as in Example 1, a comparative upconversion emission evaluation sample was fabricated by the same procedures as in Example 1, and subsequently, the upconversion emission intensity was measured under the same conditions as in Example 1, except that the commercial product of the Ionic Liquid #1 used in Preparation Example 1 of the ionic liquid (C) (which produced water with a pH of 3.9 when washed with a volume of ultrapure water that is 9 times as much as the volume of the ionic liquid (C)) was used as it was in place of the Ionic Liquid #1 obtained as the ionic liquid (C) by the same method as in Preparation Example 1 of the ionic liquid (C).

Results demonstrate that the comparative upconversion emission evaluation sample has a visually very low upconversion emission intensity, far lower than the upconversion emission intensity of the upconversion emission evaluation sample obtained in in Example 1. The upconversion emission intensity of the comparative upconversion emission evaluation sample was monitored for temporal changes. The monitoring revealed that the upconversion emission intensity started to decline rapidly immediately after the start of irradiation with Continuous Wave Laser Light #1 and that the upconverted light emission practically disappeared approximately 10 seconds after the start of irradiation. The comparative upconversion emission evaluation sample thus turned out to be extremely unstable under irradiation with Continuous Wave Laser Light #1.

The results of Example 1 and Comparative Example 1 show that the optical wavelength conversion element of Example 1 as an optical wavelength conversion element in accordance with the present invention has a good stability in upconverted light emission. More specifically, replacing the commercial product of the Ionic Liquid #1 used in Preparation Example 1 of the ionic liquid (C) (which produces water with a pH of 3.9 when washed with a volume of ultrapure water that is 9 times as much as the volume of the ionic liquid (C)) with the Ionic Liquid #1 as the ionic liquid (C) (which produces water with a pH larger than 5 when washed with a volume of ultrapure water that is 9 times as much as the volume of the ionic liquid (C)) remarkably improves the stability of the optical wavelength conversion element under photoirradiation, successfully upgrading the stability to sufficient levels for practical applications.

### Example 2

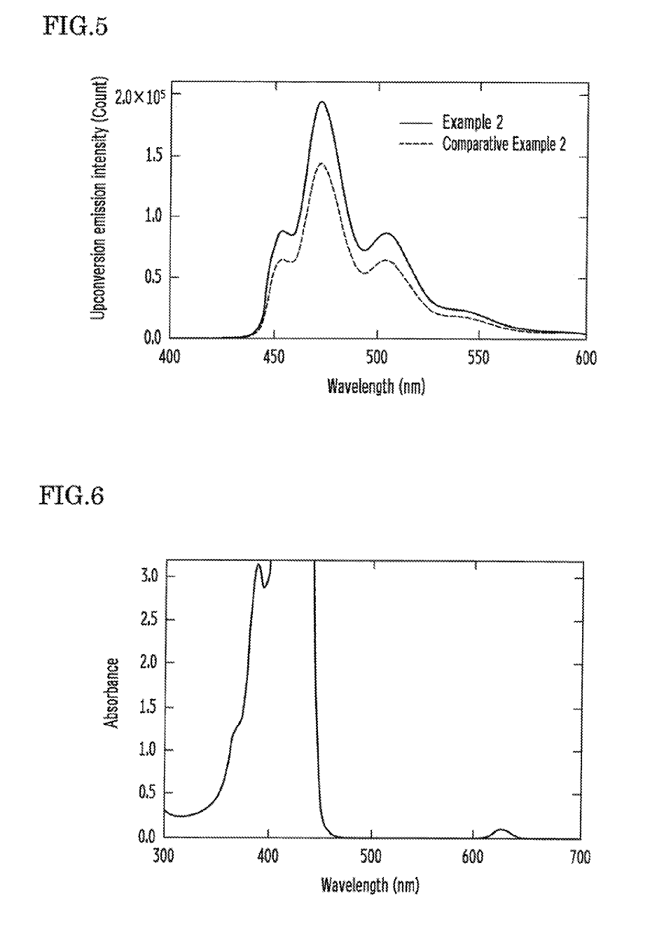

A visually homogeneous and transparent liquid as an optical wavelength conversion element was prepared by the same procedures as in Example 1, an upconversion emission evaluation sample and an absorption spectrum measuring sample were fabricated by the same procedures as in Example 1, and subsequently, the upconversion emission spectrum, upconversion emission intensities (peak intensities and integral intensities), and absorption spectrum were measured under the same conditions as in Example 1, except that the Ionic Liquid #2 obtained as the ionic liquid (C) in Preparation Example 2 of the ionic liquid (C) was used in place of the Ionic Liquid #1 obtained as the ionic liquid (C) in Preparation Example 1 of the ionic liquid (C). The upconversion emission spectrum and absorption spectrum obtained from the measurement are shown respectively in FIGS. 5 and 6.

### Comparative Example 2

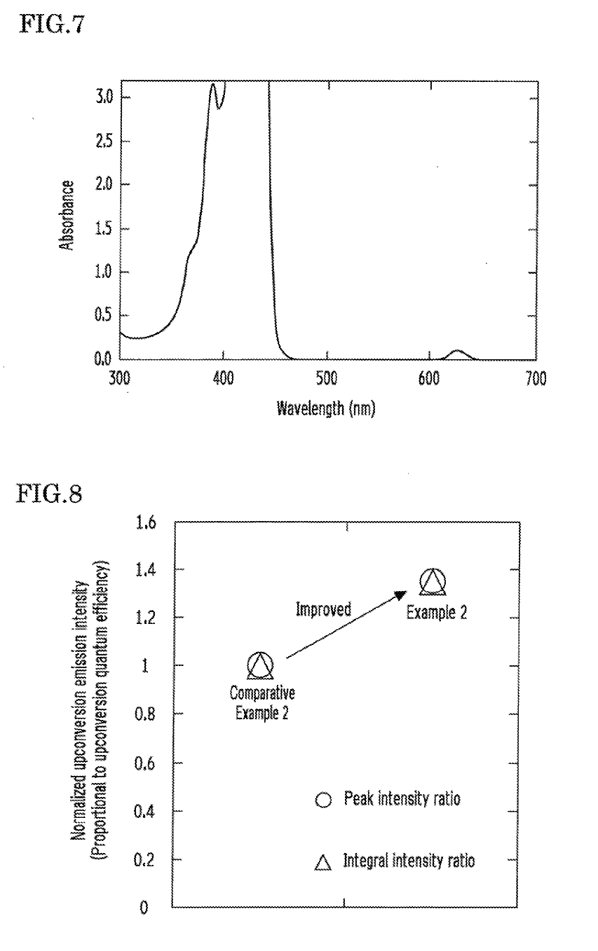

A visually homogeneous and transparent liquid as a comparative optical wavelength conversion element was prepared by the same procedures as in Example 1, a comparative upconversion emission evaluation sample and a comparative absorption spectrum measuring sample were prepared by the same procedures as in Example 1, and subsequently, the upconversion emission spectrum, upconversion emission intensities (peak intensities and integral intensities), and absorption spectrum were measured under the same conditions as in Example 1, except that the commercial product of the Ionic Liquid #2 used in Preparation Example 2 of the ionic liquid (C) was used as it was in place of the Ionic Liquid #1 obtained as the ionic liquid (C) in Preparation Example 1 of the ionic liquid (C)). The upconversion emission spectrum and absorption spectrum obtained from the measurement are shown respectively in FIGS. 5 and 7.

To allow comparison of the upconversion emission intensity of the upconversion emission evaluation sample of Example 2 and the upconversion emission intensity of the upconversion emission evaluation sample of Comparative Example 2, these upconversion emission intensities were normalized by letting the upconversion emission intensities (peak intensities and integral intensities) of the upconversion emission evaluation sample of Comparative Example 2 be equal to 1. FIG. 8 shows the normalized upconversion emission intensities (peak intensities and integral intensities) of the upconversion emission evaluation samples of Example 2 and Comparative Example 2 on the vertical axis. The magnitude of upconversion emission intensity is proportional to upconversion quantum yield (optical wavelength conversion efficiency).

The comparative upconversion emission evaluation sample of the present comparative example was fabricated simultaneously with the upconversion emission evaluation sample of Example 2 in the same batch on the same day. In addition, the upconversion emission intensity of the comparative upconversion emission evaluation sample of the present comparative example was measured on the same day and under the same optical measurement conditions as the upconversion emission intensity of the upconversion emission evaluation sample of Example 2. Therefore, the present comparative example allows quantitative comparisons of upconversion emission intensity measurements between the present comparative example and Example 2.

As shown in FIG. 8, the optical wavelength conversion element of Example 2, which was the optical wavelength conversion element in accordance with the present invention prepared by using the Ionic Liquid #2 (ionic liquid (C) producing water with a pH larger than 5 when washed with a volume of ultrapure water that is 9 times as much as the volume of the ionic liquid (C)), exhibited an upconversion emission intensity that increased (improved) by as much as about 1.4 times over the upconversion emission intensity of the optical wavelength conversion element of Comparative Example 2, which was a comparative optical wavelength conversion element prepared by using commercial the Ionic Liquid #2 producing water with a pH of less than or equal to 5 when washed with a volume of ultrapure water that is 9 times as much as the volume of the ionic liquid (C). As described in the foregoing, the comparison between Example 1 and Comparative Example 1 and the comparison between Example 2 and Comparative Example 2 demonstrate the advantages and improving effects of the use of the ionic liquid (C) in optical wavelength conversion elements.

### Example 3

### Preparation of Optical Wavelength Conversion Element

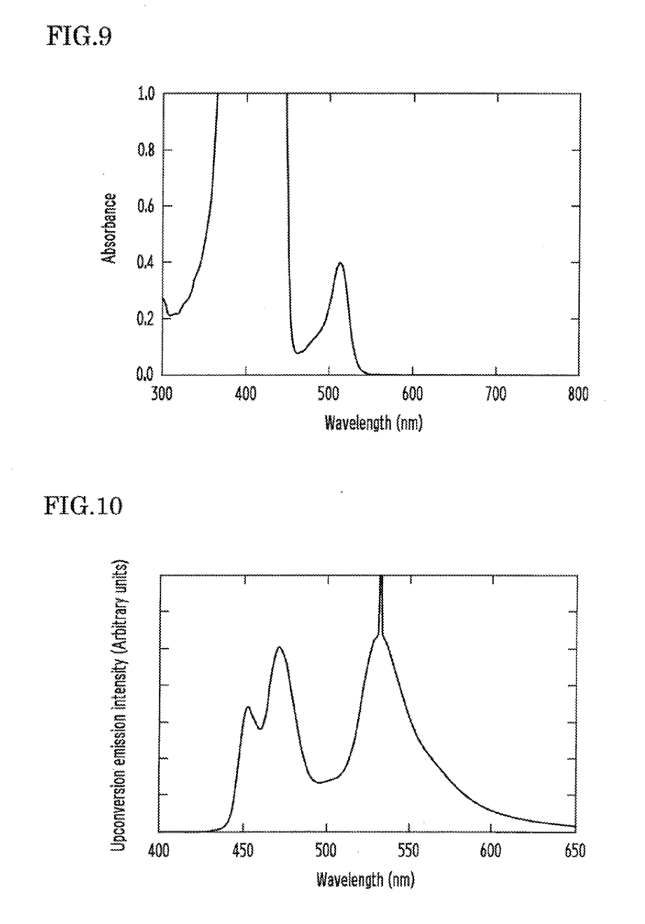

A visually homogeneous and transparent liquid as an optical wavelength conversion element was obtained by the same procedures as in Example 1, except that the Ionic Liquid #2 (400 μL) obtained in Preparation Example 2 of the ionic liquid (C) was used in place of the Ionic Liquid #1 (400 μL) obtained as the ionic liquid (C) in Preparation Example 1 of the ionic liquid (C) and that the 6×10⁻⁴ M toluene solution (about 40 μL) of the organic photosensitizing molecules (A) (2-iodo-1,3,5,7-tetramethyl-8-phenyl-4,4-difluoroboradiazaindacene) obtained in Synthesis Example 1 of the organic photosensitizing molecules (A) was used in place of the 2×10⁻⁴ M toluene solution (about 20 μL) of meso-tetraphenyl-tetrabenzoporphyrin palladium. Subsequently, an upconversion emission evaluation sample and an absorption spectrum measuring sample were fabricated by the same procedures as in Example 1. The absorption spectrum was measured under the same conditions as in Example 1. The absorption spectrum obtained from the measurement is shown in FIG. 9.

### Measurement of Upconversion Quantum Yield of Optical Wavelength Conversion Element

The upconversion quantum yield (optical wavelength conversion efficiency) of the upconversion emission evaluation sample fabricated in the present example was measured in the following manner based on a reference method, similarly to the measuring method described in Patent Document 3, paragraph [0099].

First, the upconversion emission evaluation sample fabricated in the present example was held in the same sample holder as that used in Example 1. Continuous wave laser light as excitation light (wavelength: 532 nm, spot diameter: about 0.8 mm, and output power: about 30 mW) was emitted from a continuous wave laser generator (manufactured by Abal OptoTek Co., Ltd. (AOTK), Product Number: Action 532S). The upconversion emission spectrum of the upconversion emission evaluation sample was measured and recorded using an electronically cooled silicon CCD (charge coupled device) detector (the same detector as that used in Example 1) mounted after a monochromator (the same monochromator as that used in Example 1). The upconversion emission spectrum obtained from the measurement is shown in FIG. 10.

Subsequently, a 1×10⁻⁵ M toluene solution of 9,10-bis(phenylethinyl)anthracene (CAS Number: 10075-85-1) was prepared. 9,10-Bis(phenylethinyl)anthracene is a pigment known to exhibit a fluorescence quantum efficiency of about 85% in non-polar solvents, such as toluene and benzene. This solution was injected into the same type of square quartz tube (inner dimensions: 1 mm×1 mm, outer dimensions: 2 mm×2 mm, and length about 25 mm) with one open end as that used in Example 1 and the present example to fill about ¾ the full length of the tube. The open end was then sealed using lead soldering, to obtain a reference sample. This reference sample was held in the same sample holder as that used in Example 1. Continuous wave laser light as excitation light (wavelength: 405 nm, spot diameter: about 0.8 mm, and output power: about 1 mW) was emitted from a continuous wave laser generator (manufactured by World Star Tech Inc., Product Number: TECBL-30GC-405) and shone onto the reference sample. The fluorescence emission spectrum of the reference sample was measured and recorded using an electronically cooled silicon CCD detector (the same detector as that used in Example 1) mounted after a monochromator (the same monochromatoer as that used in Example 1).

The upconversion emission spectrum of the upconversion emission evaluation sample and the fluorescence emission spectrum of the reference sample, recorded as above, were then corrected with respect to the wavelength dependence in the diffraction efficiency of a diffraction grating placed in the monochromator and the wavelength dependence in the detection sensitivity of the electronically cooled silicon CCD detector, to correct the distortions in the recorded spectral profile. Then, the upconversion quantum yield of the upconversion emission evaluation sample was determined from information on the absorbance and excitation light intensity of the upconversion emission evaluation sample and the reference sample under light of excitation wavelength by using a formula commonly used by the person skilled in the art, the information being extracted from the corrected spectra (upconversion emission spectrum and fluorescence emission spectrum) of the samples.

The procedure described above showed that the optical wavelength conversion element obtained in the present example had an upconversion quantum yield of 20.1%.

### Example 4

A visually homogeneous and transparent liquid as an optical wavelength conversion element was prepared by the same procedures as in Example 3, except that a 3×10⁻⁴ M toluene solution (about 20 μL) of the organic photosensitizing molecules (A) (2,6-diiodo-1,3,5,7-tetramethyl-8-phenyl-4,4-difluoroboradiazaindacene) obtained in Synthesis Example 2 of the organic photosensitizing molecules (A) was used in place of the 6×10⁻⁴ M toluene solution (about 40 μL) of the organic photosensitizing molecules (A) (2-iodo-1,3,5,7-tetramethyl-8-phenyl-4,4-difluoroboradiazaindacene) obtained in Synthesis Example 1 of the organic photosensitizing molecules (A).

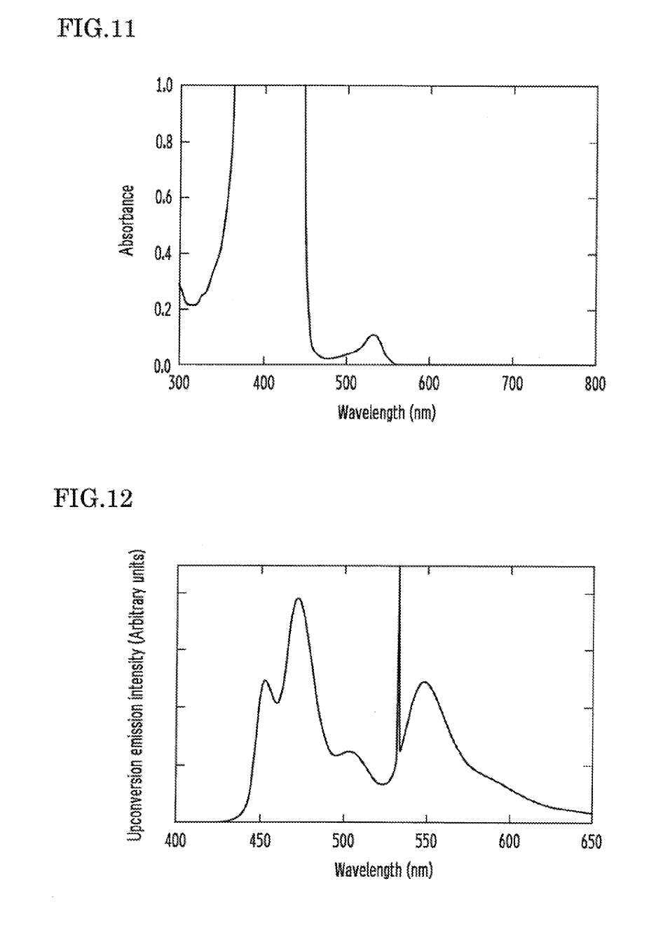

Next, an upconversion emission evaluation sample and an absorption spectrum measuring sample were fabricated, and the absorption spectrum, upconversion emission spectrum, and upconversion quantum yield were measured by the same procedures as in Example 3, except that the optical wavelength conversion element obtained in the present example was used. The absorption spectra and the upconversion emission spectra, both obtained from the measurement, are shown in FIG. 11 and FIG. 12 respectively. The optical wavelength conversion element obtained in the present example had an upconversion quantum yield of 16.8%.

### Comparison of Examples 3 and 4 and Non-Patent Document 6

In Non-patent Document 6, an optical wavelength conversion element was prepared using, as organic photosensitizing molecules and organic light-emitting molecules, the same types of molecules as those used in Example 3: namely, the organic photosensitizing molecules (A) (2-iodo-1,3,5,7-tetramethyl-8-phenyl-4,4-difluoroboradiazaindacene) obtained in Synthesis Example 1 of the organic photosensitizing molecules (A) and perylene respectively. A traditional organic solvent (acetonitrile) was used as a medium for the optical wavelength conversion element. Non-patent Document 6 also reports that the optical wavelength conversion element was irradiated with continuous wave laser light with a wavelength of 532 nm as excitation light and that the upconversion quantum yield of the element was measured to be 2.4%.

Still referring to Non-patent Document 6, an optical wavelength conversion element was prepared using, as organic photosensitizing molecules and organic light-emitting molecules, the same types of molecules as those used in Example 4: namely, the organic photosensitizing molecules (A) (2,6-diiodo-1,3,5,7-tetramethyl-8-phenyl-4,4-difluoroboradiazaindacene) obtained in Synthesis Example 2 of the organic photosensitizing molecules (A) and perylene respectively. A traditional organic solvent (acetonitrile) was used as a medium for the optical wavelength conversion element. Non-patent Document 6 also reports that the optical wavelength conversion element was irradiated with continuous wave laser light with a wavelength of 532 nm as excitation light and that the upconversion quantum yield of the element was measured to be 5.4%.

It is not particularly easy to make a straightforward comparison of Examples 3 and 4 and Non-patent Document 6 because Examples 3 and 4 and Non-patent Document 6 involve slightly different measurement conditions. The upconversion quantum yields achieved in Examples 3 and 4 (20.1% and 16.8%), however, are greater approximately by one order of magnitude than the upconversion quantum yields determined through measurement in Comparative Examples 3 and 4 (2.4% and 5.4%). These figures indicate that Examples 3 and 4 made remarkable improvements.

### Example 5

Subsequently, ionic liquids with various viscosities were studied as the ionic liquid (C). The effects of different ionic liquids on the optical wavelength conversion efficiency (upconversion quantum yield) of the optical wavelength conversion element were earnestly studied. Results were surprising and demonstrated for the first time that the viscosity of the ionic liquid is an extremely important design factor that dominantly affects the optical wavelength conversion efficiency of the optical wavelength conversion element.

### Measurement of Viscosity of Ionic Liquid (C)

The viscosities of the Ionic Liquids #1, #2, #3, #4, #5, #6, #7, #8, #9, #10, #11, #12, #13, and #14, each as the ionic liquid (C) prepared in Preparation Example 3 of the ionic liquid (C) for use in the present example, were measured at 26° C. with a cone and plate viscometer (manufactured by Brookfield Engineering Laboratories, Inc., Product Name: R/S Plus). At 26° C., the Ionic Liquid #1 had a viscosity of 86.8 mPa·s; the Ionic Liquid #2 had a viscosity of 94.5 mPa·s; the Ionic Liquid #3 had a viscosity of 28.4 mPa·s; the Ionic Liquid #4 had a viscosity of 45.7 mPa·s; the Ionic Liquid #5 had a viscosity of 47.0 mPa·s; the Ionic Liquid #6 had a viscosity of 70.3 mPa·s; the Ionic Liquid #7 had a viscosity of 87.3 mPa·s; the Ionic Liquid #8 had a viscosity of 57.9 mPa·s; the Ionic Liquid #9 had a viscosity of 86.7 mPa·s; the Ionic Liquid #10 had a viscosity of 71.8 mPa·s; the Ionic Liquid #11 had a viscosity of 94.7 mPa·s; the Ionic Liquid #12 had a viscosity of 64.8 mPa·s; the Ionic Liquid #13 had a viscosity of 200 mPa·s; and the Ionic Liquid #14 had a viscosity of 584 mPa·s.

### Preparation of Optical Wavelength Conversion Element

Fourteen optical wavelength conversion elements were prepared by the same procedures as that used in Example 1, except that the Ionic Liquids #1, #2, #3, #4, #5, #6, #7, #8, #9, #10, #11, #12, #13, and #14, each as the ionic liquid (C) prepared in Preparation Example 3 of the ionic liquid (C), were used in place of the Ionic Liquid #1 obtained as the ionic liquid (C) in Preparation Example 1 of the ionic liquid (C).

### Measurement of Upconversion Emission Intensity of Optical Wavelength Conversion Element

Fourteen upconversion emission evaluation samples were fabricated from the 14 optical wavelength conversion elements by the same procedures as in Example 1. Subsequently, the upconversion emission intensity of each sample was measured under the same conditions as in Example 1.

By letting the upconversion emission intensity of the upconversion emission evaluation sample fabricated from the Ionic Liquid #2 (ionic liquid (C)) be equal to 1, the upconversion emission intensities of the upconversion emission evaluation samples fabricated from the other ionic liquids (C) were normalized relatively to examine the effects of the viscosities of the ionic liquids on the upconversion efficiency.

The aforementioned 14 ionic liquids (C) in Preparation Example 3 of the ionic liquid (C) and 14 upconversion emission evaluation samples in the present example were prepared under the same conditions. In addition, the upconversion emission intensities of the 14 upconversion emission evaluation samples were measured under the same optical measurement conditions. Furthermore, all measurements in the present example were performed at an environmental temperature of 26±1° C. This arrangement allowed quantitative comparisons of upconversion emission intensity measurements between the 14 upconversion emission evaluation samples.

In addition, to check reproducibility, the cycle of fabricating an upconversion emission evaluation sample from either the Ionic Liquid #13 or #14 and measuring the upconversion emission intensity of the sample was repeated 3 times for the Ionic Liquid #13 and twice for the Ionic Liquid #14.

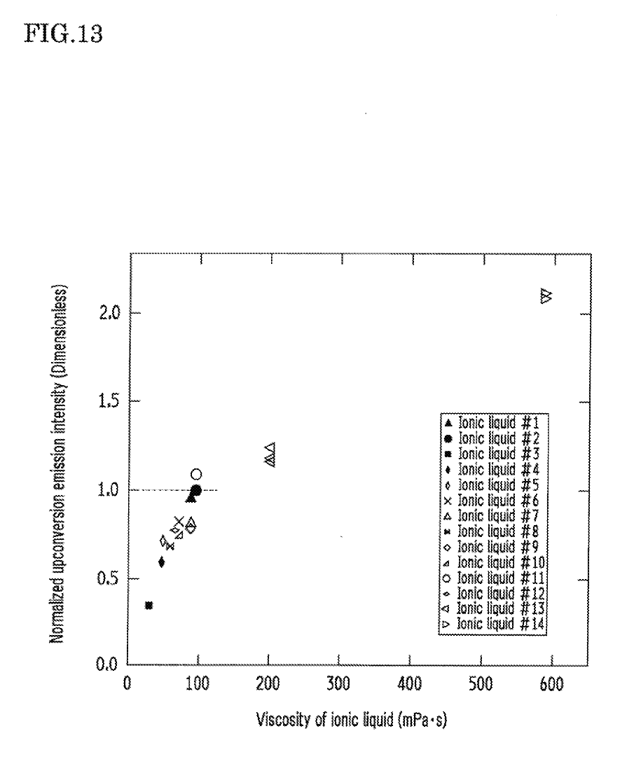

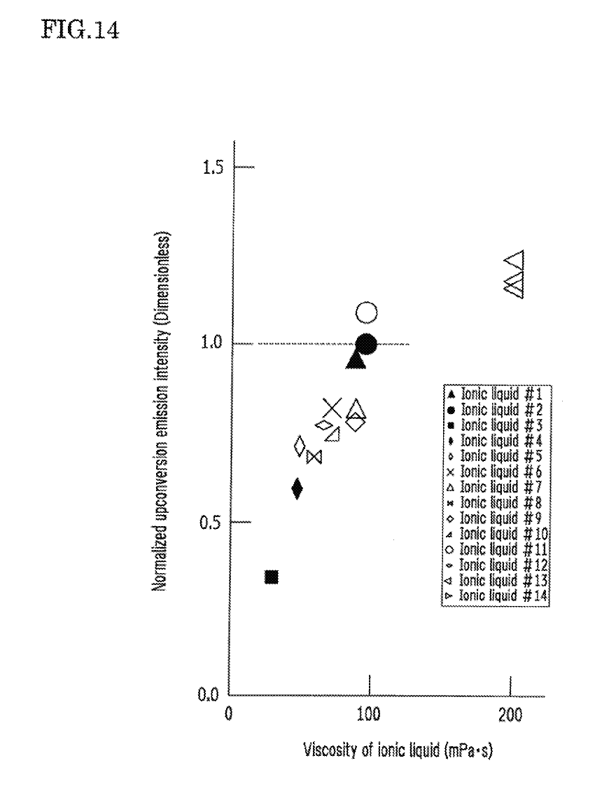

The graph in FIG. 13 plots the viscosities of the Ionic Liquids #1 to #14 (ionic liquids (C)) at 26° C. on the horizontal axis and the upconversion emission intensities of all the upconversion emission evaluation samples, normalized by letting the upconversion emission intensity of the upconversion emission evaluation sample fabricated from the Ionic Liquid #2 (ionic liquid (C)) be equal to 1, on the vertical axis. FIG. 14 is an enlarged view of a part of the graph in FIG. 13 where data from the upconversion emission evaluation samples fabricated from the Ionic Liquids #1 to #13 (ionic liquids (C)) are plotted. In FIGS. 13 and 14, the plots for the upconversion emission evaluation samples are accompanied by indications of the types of ionic liquids used in the fabrication thereof.

There were slight variances in the measured absorbance values at excitation wavelength (632.8 nm) of the upconversion emission samples used for the evaluation, and therefore corrected for this variance to eliminate possible undesirable effects. FIGS. 13 and 14 show the corrected values on the vertical axes.

The results shown in FIGS. 13 and 14 indicate that there is a strong and distinct correlation between the relative upconversion emission intensity of an optical wavelength conversion element (which is proportional to the upconversion quantum yield) and the viscosity of the ionic liquid (C) used in that optical wavelength conversion element. The results also demonstrate that the use of an ionic liquid (C) with a greater viscosity will lead to a greater upconversion emission intensity (in other words, a greater upconversion quantum efficiency) at least in the range shown on the horizontal axes in FIGS. 13 and 14. These findings undoubtedly show for the first time that the viscosity of the ionic liquid used in an optical wavelength conversion element is an extremely important efficiency controlling factor in the design of the optical wavelength conversion element.

### Measurement of Upconversion Quantum Yield of Optical Wavelength Conversion Element

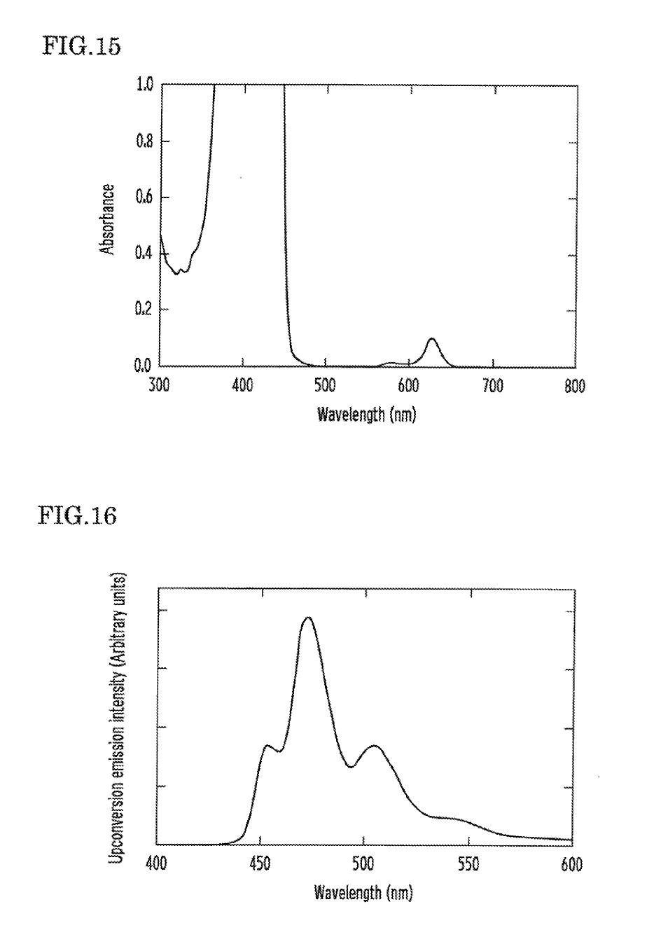

The absorption spectrum and upconversion emission spectrum of the optical wavelength conversion element, as well as the upconversion quantum yield (optical wavelength conversion efficiency) of the optical wavelength conversion element, were measured by the same procedures as in Example 3, except that Continuous Wave Laser Light #1 as excitation light (wavelength: 632.8 nm, spot diameter: about 0.8 mm, and output power: about 28 mW) emitted from the same continuous wave laser generator as that used in Example 1 was shone onto the upconversion emission evaluation sample fabricated from the Ionic Liquid #14 (ionic liquid (C) in the present example). The absorption spectrum and upconversion emission spectrum obtained from the measurement are shown in FIGS. 15 and 16 respectively. The optical wavelength conversion element had an upconversion quantum yield of 15.4%.

### Example 6

### Preparation of Optical Wavelength Conversion Element

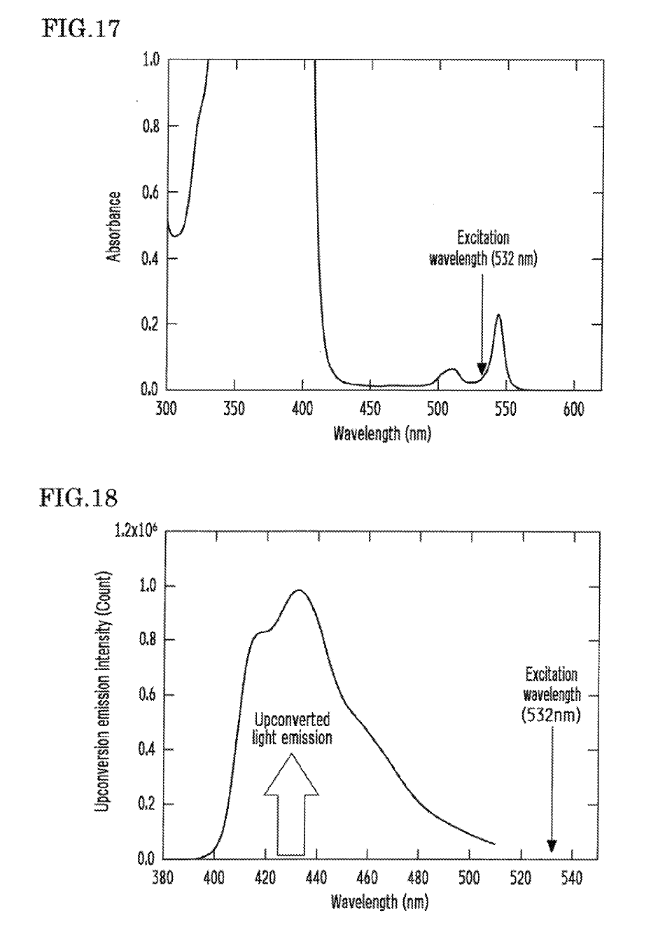

A visually homogeneous and transparent liquid as an optical wavelength conversion element was obtained by the same procedures as in Example 1, except that the Ionic Liquid #14 (400 μL) obtained in Preparation Example 3 of the ionic liquid (C) was used in place of the Ionic Liquid #1 (400 μL) obtained as the ionic liquid (C) in Preparation Example 1 of the ionic liquid (C), that a 4×10⁻⁴ M toluene solution of octaethylporphyrin palladium was used as the organic photosensitizing molecules (A) in place of the 2×10⁻⁴ M toluene solution of meso-tetraphenyl-tetrabenzoporphyrin palladium, and that a 4×10⁻³ M toluene solution of 9,10-diphenylanthracene was used as the organic light-emitting molecules (B) in place of the 4×10⁻³ M toluene solution of perylene. Subsequently, an absorption spectrum measuring sample and an upconversion emission evaluation sample were fabricated by the same procedures as in Example 1. The absorption spectrum of each sample was measured under the same conditions as in Example 1. The absorption spectrum obtained from the measurement is shown in FIG. 17.

Next, the upconversion emission spectrum of the upconversion emission evaluation sample was measured by the same procedures as in Example 3, except that the optical wavelength conversion element fabricated in the present example was used. The upconversion emission spectrum obtained from the measurement is shown in FIG. 18.

The upconversion quantum yield of the upconversion emission evaluation sample was measured under irradiation with continuous wave laser light of 30-mW output power by the same procedures as in Example 3. Additionally, the upconversion quantum yield of the upconversion emission evaluation sample was measured under irradiation with continuous wave laser light of 20-mW output power by the same procedures as in Example 3, except that the output power was changed to 20 mW. Results of the measurement indicate that the optical wavelength conversion element fabricated in the present example had an upconversion quantum yield of 31.3% under the 30-mW output power and 29.2% under the 20-mW output power.

### Example 7

### Measurement of Viscosity of Ionic Liquid (C)

The viscosities of the Ionic Liquids #1, #2, #3, #4, #5, #9, #10, #12, #13, and #14, each as the ionic liquid (C) prepared in Preparation Example 3 of the ionic liquid (C) for use in the present example, were measured at 20° C. with a cone and plate viscometer (the same viscometer as that used in Example 5).

### Preparation of Optical Wavelength Conversion Element

Ten optical wavelength conversion elements were prepared by the same procedures as in Example 6, except that the Ionic Liquids #1, #2, #3, #4, #5, #9, #10, #12, #13, and #14, each as the ionic liquid (C) prepared in Preparation Example 3 of the ionic liquid (C), were used in place of the Ionic Liquid #14 obtained as the ionic liquid (C) in Preparation Example 2 of the ionic liquid (C).

### Measurement of Upconversion Emission Intensity of Optical Wavelength Conversion Element

10 types of upconversion emission evaluation samples were fabricated by the same procedures as in Example 1 using the 10 types of optical wavelength conversion elements. Subsequently, the upconversion emission intensity of each sample was measured under the same conditions as in Example 3.

By letting the upconversion emission intensity of the upconversion emission evaluation sample fabricated from the Ionic Liquid #2 (ionic liquid (C)) be equal to 1, the upconversion emission intensities of the upconversion emission evaluation samples fabricated from the other ionic liquids (C) were normalized relatively to examine the effects of the viscosities of the ionic liquids on the upconversion efficiency.

The upconversion emission intensities of the 10 types of upconversion emission evaluation samples were measured under the same optical measurement conditions. Furthermore, all measurements in the present example were performed at an environmental temperature of 20±+1° C. This arrangement allowed quantitative comparisons of upconversion emission intensity measurements between the 10 types of upconversion emission evaluation samples.

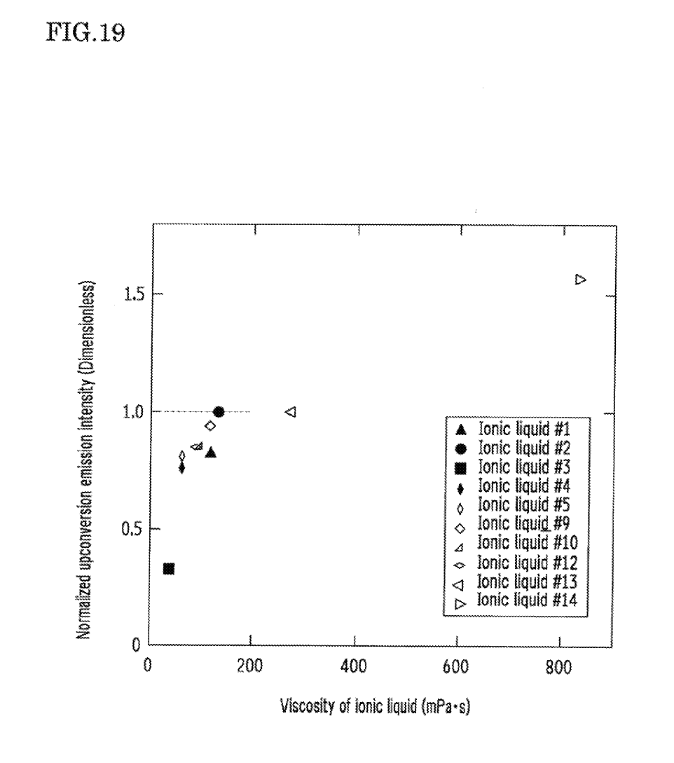

The graph in FIG. 19 plots the viscosities of the Ionic Liquids #1, #2, #3, #4, #5, #9, #10, #12, #13, and #14 (ionic liquids (C)) at 20° C. on the horizontal axis and the upconversion emission intensities of all the upconversion emission evaluation samples, normalized by letting the upconversion emission intensity of the upconversion emission evaluation sample fabricated from the Ionic Liquid #2 (ionic liquid (C)) be equal to 1, on the vertical axis. In FIG. 19, the plots for the upconversion emission evaluation samples are accompanied by indications of the types of ionic liquids used in the fabrication thereof.

The results shown in FIGS. 13, 14, and 19 indicate that the relative upconversion emission intensity of an optical wavelength conversion element (which is proportional to the upconversion quantum yield) increases with an increase in the viscosity of the ionic liquid (C) used in the optical wavelength conversion element, regardless of whichever types of organic photosensitizing molecules (A) and organic light-emitting molecules (B) are used.

### Synthesis Example 1 of Gelator (D)

A compound, poly [(dimethylimino)hexane-1,6-diyl(dimethylimino)methylene-1,4-phenylene carbonylimino trans-cyclohexane-1,4-diyliminocarbonyl-1,4-phenylenemethylene bis(trifluoromethane sulfonyl)amide] of

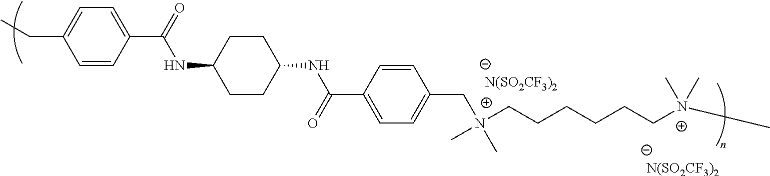

was synthesized as the gelator (D) (ionic gelator) by the method described by Jun'ichi Nagasawa, et al., ACS Macro Lett., 2012, 1 (9), pp. 1108-1112. The obtained compound had a degree of polymerization, n, of about 62 as calculated from a weight average molecular weight. The compound was identified by the following NMR spectroscopy.

¹H NMR (400 MHz, DMSO-d₆): δ 1.28-1.55 (m, 8H), 1.75-1.98 (m, 8H), 2.95 (s, 12H), 3.22-3.37 (m, 4H), 3.75-3.88 (m, 2H), 4.56 (s, 4H), 7.64 (d, J=7.4 Hz, 4H), 7.99 (d, J=7.4 Hz, 4H), 8.40 (d, J=6.9 Hz, 2H) ppm

### Example 8

### Preparation of Mixture of Gelator (D) and Ionic Liquid

First, 8 mg of the ionic gelator obtained in Synthesis Example 1 of the gelator (D) was put into a washed glass vial (capacity: 8 mL), and 150 μL of methanol was added. Next, the vial was capped and heated for 12 minutes on a hotplate set at 80° C. Next, 400 μL of the Ionic Liquid #2 (ionic liquid (C)) (purified 1-butyl-2,3-dimethylimidazolium bis(trifluoromethylsulfonyl)imide) was added into the vial. Immediately after that, the contents of the vial were thoroughly mixed by repeated suction-and-ejection using the same type of glass Pasteur pipette as that used in Preparation Example 1 of the ionic liquid (C) until a uniform mixture was obtained. Then, after the vial was capped, the mixture was subjected to ultrasonic dispersion for 15 minutes in the same ultrasonic bath sonicator as that used in Example 1. Next, the vial was heated for 10 minutes on a hotplate set at 80° C. Subsequently, the vial was uncapped, put in the same vacuum dry oven as that used in Preparation Example 1 of the ionic liquid (C), and vacuum heated at 90° C. for 2 hours. The vial was taken out of the vacuum dry oven when the temperature was lowered to 80° C. The vial was then capped and stored overnight in a dark place to cool down. A mixture of an ionic gelator and 1-butyl-2,3-dimethylimidazolium bis(trifluoromethylsulfonyl)imide (gel; “Gel Stock 1”) as a mixture of the gelator (D) and an ionic liquid was hence obtained with a gelator concentration of 20 g/L.

### Preparation of Ionic Liquid Solution of Organic Photosensitizing Molecules (A) and Organic Light-Emitting Molecules (B)

First, 360 μL of purified 1-butyl-2,3-dimethylimidazolium bis(trifluoromethylsulfonyl)imide (ionic liquid (C)) (manufactured by IoLiTec Ionic Liquids Technologies GmbH) was put into a washed glass vial (capacity: 8 mL), and a 4×10⁻³ M toluene solution of perylene (250 μL) was added as the organic light-emitting molecules (B).

Next, the contents of the vial were thoroughly mixed by repeated suction-and-ejection using the same type of glass Pasteur pipette as that used in Example 1 until a uniform mixture was obtained. Then, after the vial was capped, the mixture was subjected to ultrasonic dispersion for 7 minutes in the same ultrasonic bath sonicator as that used in Example 1. Next, the vial was uncapped and immediately after that, put in a pass box of a glovebox. The pass box, containing the vial, was vacuumed for 1 hour using the same scroll pump as that used in Example 1 to remove toluene.

Furthermore, a 4×10⁻³ M toluene solution of perylene (200 μL) as the organic light-emitting molecules (B) and a 2×10⁻⁴ M toluene solution of meso-tetraphenyl-tetrabenzoporphyrin palladium (50 μL) as the organic photosensitizing molecules (A) were added to the contents of the vial.

Next, the contents of the vial were thoroughly mixed by repeated suction-and-ejection using the same type of glass Pasteur pipette as that used in Preparation Example 1 of the ionic liquid (C) until a uniform mixture was obtained. Then, after the vial was capped, the mixture was subjected to ultrasonic dispersion for 7 minutes in the same ultrasonic bath sonicator as that used in Example 1. Next, the vial was uncapped and immediately after that, put in a pass box of a glovebox. The pass box, containing the vial, was vacuumed for 2 hours using the same scroll pump as that used in Example 1 to remove toluene. Next, the vial was transferred into the main box of the glovebox and capped in argon atmosphere before it was taken out of the glovebox. A 1-butyl-2,3-dimethylimidazolium bis(trifluoromethylsulfonyl)imide solution of perylene and meso-tetraphenyl-tetrabenzoporphyrin palladium (“sample solution”) was hence obtained as an ionic liquid solution of the organic photosensitizing molecules (A) and the organic light-emitting molecules (B).

### Mixing and Sealing

A vial containing Gel Stock 1 (“Gel Stock vial”) and a vial containing the sample solution (“sample vial”) were placed on a hotplate set at 80-90° C. and preheated for 3 to 10 minutes. Next, 40 μL of Gel Stock 1 measured out of the Gel Stock vial was added to the sample solution in the sample vial. The contents of the sample vial were thoroughly mixed by repeated suction-and-ejection using the same type of glass Pasteur pipette as that used in Preparation Example 1 of the ionic liquid (C) until a uniform mixture was obtained. Next, the sample vial, still uncapped, was put into the same vacuum dry oven as that used in Preparation Example 1 of the ionic liquid (C) and vacuum heated at 90° C. for 1 hour before it was taken out of the vacuum dry oven.

Next, an aluminum vial holder was preheated for about 30 minutes on a hotplate set at 120° C. The preheated vial holder was placed inside a pass box of a glovebox. Immediately after that, the sample vial taken out of the vacuum dry oven was placed inside the vial holder. The pass box, containing the vial holder, was vacuumed for 5 minutes using the same scroll pump as that used in Example 1. Next, inside the main box (argon atmosphere) (of the glovebox), a portion of the sample solution in the sample vial was injected into a quartz tube with one open end (inner dimensions: 2 mm on each side) through a syringe with a hypodermic needle. The sample vial and the quartz tube were vacuumed for 25 hours using the same turbomolecular pump as that used in Example 1 in the same vacuum chamber as that used in Example 1 set in the glovebox. Thereafter, the open end of the quartz tube was sealed using soldering in the main box of the glovebox.

An optical wavelength conversion element in accordance with an example of the present invention was hence obtained. This optical wavelength conversion element was sealed in a quartz tube with the oxygen content thereof sufficiently removed and if reshaped, could be used as a photon upconversion filter.

The optical wavelength conversion element of the present example had a volume that was approximately equal to the volume of the ionic liquid (400 μL), or a primary component thereof. The optical wavelength conversion element had a gelator concentration (“gel concentration”) of about 2 g/L, a meso-tetraphenyl-tetrabenzoporphyrin palladium concentration of about 2.5×10⁻⁵ M, and a perylene concentration of about 4.5×10⁻³ M.

### Example 9

### Preparation of Mixture of Gelator (D) and Ionic Liquid

Gel Stock 1 with a gel concentration of 20 g/L was obtained by the same procedures as in Example 8.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 340 μL.

### Mixing and Sealing

An optical wavelength conversion element in accordance with an example of the present invention was obtained with a gel concentration of 3 g/L by the same procedures as in Example 8, except that the sample solution obtained in the present example was used and that the amount of Gel Stock 1 used was changed from 40 μL to 60 μL.

### Example 10

### Preparation of Mixture of Gelator (D) and Ionic Liquid

A mixture of an ionic gelator and 1-butyl-2,3-dimethylimidazolium bis(trifluoromethylsulfonyl)imide (solution; “Gel Stock 2”) was obtained with a gel concentration of 40 g/L by the same procedures as in Example 8, except that the amount of the ionic gelator used was changed from 8 mg to 16 mg and that the heating duration following the dropwise dispensing of methanol was changed from 12 minutes to 15 minutes.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 350 μL.

### Mixing and Sealing

An optical wavelength conversion element in accordance with an example of the present invention was obtained with a gel concentration of 5 g/L by the same procedures as in Example 8, except that the sample solution obtained in the present example was used and that Gel Stock 2 (50 μL) was used in place of Gel Stock 1 (40 μL).

### Example 11

### Preparation of Mixture of Gelator (D) and Ionic Liquid

Gel Stock 2 was obtained with a gel concentration of 40 g/L by the same procedures as in Example 10.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 330 μL.

### Mixing and Sealing

An optical wavelength conversion element in accordance with an example of the present invention was obtained with a gel concentration of 7 g/L by the same procedures as in Example 8, except that the sample solution obtained in the present example was used and that Gel Stock 2 (70 μL) was used in place of Gel Stock 1 (40 μL).

### Example 12

### Preparation of Mixture of Gelator (D) and Ionic Liquid

Gel Stock 2 was obtained with a gel concentration of 40 g/L by the same procedures as in Example 10.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 300 μL.

### Mixing and Sealing

An optical wavelength conversion element in accordance with an example of the present invention was obtained with a gel concentration of 10 g/L by the same procedures as in Example 8, except that the sample solution obtained in the present example was used and that Gel Stock 2 (100 μL) was used in place of Gel Stock 1 (40 μL).

### Example 13

### Preparation of Mixture of Gelator (D) and Ionic Liquid

A mixture of an ionic gelator and 1-butyl-2,3-dimethylimidazolium bis(trifluoromethylsulfonyl)imide (solution; “Gel Stock 3”) was obtained with a gel concentration of 120 g/L by the same procedures as in Example 8, except that the amount of the ionic gelator used was changed from 8 mg to 48 mg and that the heating duration immediately following the dropwise dispensing of methanol was changed from 12 minutes to 20 minutes.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 350 μL.

### Mixing and Sealing

An optical wavelength conversion element in accordance with an example of the present invention was obtained with a gel concentration of 15 g/L by the same procedures as in Example 8, except that the sample solution obtained in the present example was used and that Gel Stock 3 (50 μL) was used in place of Gel Stock 1 (40 μL).

### Example 14

### Preparation of Mixture of Gelator (D) and Ionic Liquid

Gel Stock 3 was obtained with a gel concentration of 120 g/L by the same procedures as in Example 8.

### Preparation of Ionic Liquid Solution of Organic Photosensitizing Molecules (A) and Organic Light-Emitting Molecules (B)

A sample solution was obtained by the same procedures as in Example 8, except that the amount of the purified 1-butyl-2,3-dimethylimidazolium bis(trifluoromethylsulfonyl)imide used as the ionic liquid (C) was changed from 360 μL to 323 μL.

### Mixing and Sealing

An optical wavelength conversion element in accordance with an example of the present invention was obtained with a gel concentration of 23 g/L by the same procedures as in Example 8, except that the sample solution obtained in the present example was used and that Gel Stock 3 (77 μL) was used in place of Gel Stock 1 (40 μL).

### Visual Observations of the Optical Wavelength Conversion Element

Each of thethe optical wavelength conversion elements obtained in Examples 8 to 14 was put in the same type of glass vial as that used in Example 1 and observed the changes with time by eyes. Results, collectively shown in Table 1 below, demonstrate that the optical wavelength conversion elements with a gel concentration greater than or equal to 3 g/L are in a gel state after 2 days.

TABLE 1

| | Gel | | | | | |
|---|---|---|---|---|---|---|
| Example | concentration | | | | | |
| No. | (g/L) | After 15 hs. | After 1 day | After 2 days | After 5 days | After 8 days |
| 8 | 2 | Liquid, | Liquid, | Liquid, | Liquid, | Liquid, |
| | | transparent | transparent | transparent | transparent | transparent |
| 9 | 3 | Fluidic, | Fluidic, | Soft gel, fluidic | Soft gel, fluidic | Soft gel, fluidic |
| | | transparent | transparent | when inclined, | when inclined, | when inclined, |
| | | | | transparent | transparent | transparent |
| 10 | 5 | Gel, partially | Gel, partially | Gel, hardly | Gel, hardly | Gel, hardly |
| | | fluidic when | fluidic when | fluidic when | fluidic when | fluidic when |
| | | inclined, | inclined, | inclined, | inclined, | inclined, |
| | | transparent | transparent | transparent | transparent | transparent |
| 11 | 7 | Firm gel, | Firm gel, | Firm gel, | Firm gel, | Firm gel, |
| | | transparent | transparent | transparent | transparent | transparent |
| 12 | 10 | Firm gel, | Firm gel, | Firm gel, | Firm gel, | Firm gel, |
| | | slightly turbid | slightly turbid | slightly turbid | slightly turbid | slightly turbid |
| 13 | 15 | Firm gel, | Firm gel, | Firm gel, | Firm gel, | Firm gel, |
| | | slightly opaque | slightly opaque | slightly opaque | slightly opaque | slightly opaque |
| 14 | 23 | Firm gel, | Firm gel, | Firm gel, | Firm gel, | Firm gel, |
| | | opaque | opaque | opaque | opaque | opaque |

### Upconversion Emission Spectrum and Upconversion Emission Intensity of Optical Wavelength Conversion Element

Each of thethe quartz tubes in which the optical wavelength conversion element obtained in Examples 8 to 14 was sealed was held in a special sample holder. The spectrum (spectral profile) and intensity of the upconverted light emission of each element were measured by the same procedures as in Example 1, except that continuous wave laser light as excitation light (wavelength (excitation wavelength): 632.8 nm, spot diameter: about 0.8 mm, output power (excitation intensity): 20 mW) was emitted from a continuous wave laser generator (manufactured by CVI Melles Griot Inc., Product Number: 25 LHP 928-249) and shone onto the quartz tubes.

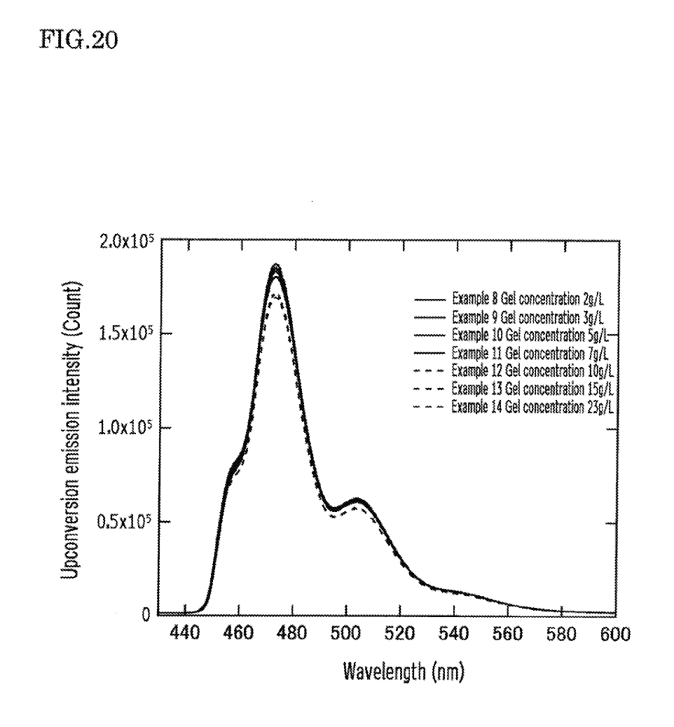

The measured upconversion emission spectra are shown in FIG. 20. The measured upconversion emission intensities (wavelength-integrated values) and peak emission intensities (relative values) are shown in Table 2 below.

TABLE 2

| | Gel | Emission intensity | Peak emission |
|---|---|---|---|
| | concentration | (wavelength-integrated | intensity |
| | (g/L) | value) | (relative value) |
| Example 8 | 2 | 3.34 × 10⁷ | 1.00 |
| Example 9 | 3 | 3.29 × 10⁷ | 0.98 |
| Example 10 | 5 | 3.42 × 10⁷ | 1.02 |
| Example 11 | 7 | 3.38 × 10⁷ | 1.01 |
| Example 12 | 10 | 3.36 × 10⁷ | 1.01 |
| Example 13 | 15 | 3.14 × 10⁷ | 0.94 |
| Example 14 | 23 | 3.12 × 10⁷ | 0.93 |

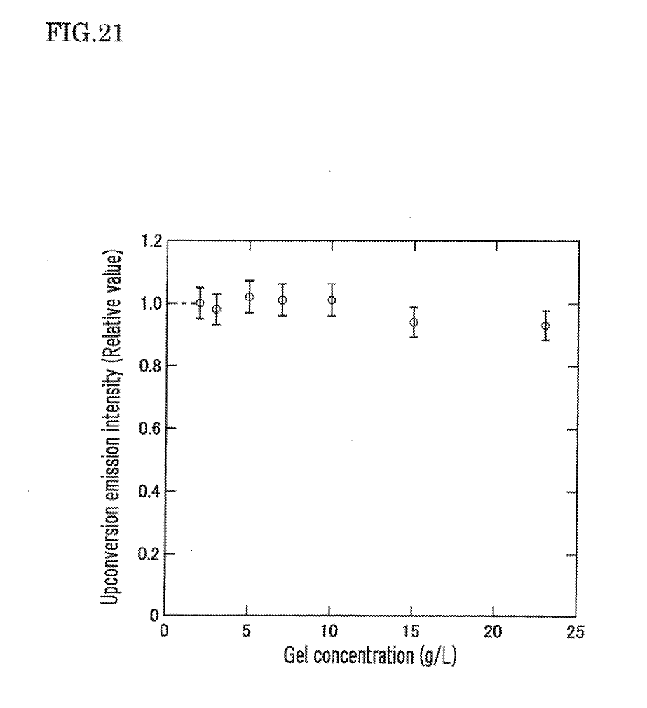

FIG. 21 shows changes in the upconversion emission intensities (peak emission intensities) (relative values) over the changes in the gel concentrations in the optical wavelength conversion elements obtained in Examples 8 to 14.

The results shown in FIGS. 20 and 21 and Table 2 reveal that the optical wavelength conversion element in accordance with the present invention has an upconversion emission intensity that is independent of the gel concentration and that the optical wavelength conversion element in accordance with the present invention has a sufficient upconversion emission intensity regardless of the gel concentration.

### REFERENCE SIGNS LIST

1 Photovoltaic layer
2 Transparent back-face electrode
3 Transparent insulating film
4 Upconversion layer
5 Light reflecting film
7 Light-receiving face electrode
8 Glass channel
9 Gas
10 Photocatalyst-containing water
11 Mechanical support

The present invention may be implemented in various forms without departing from its spirit and main features. Therefore, the aforementioned examples are for illustrative purposes only in every respect and should not be subjected to any restrictive interpretations. The scope of the present invention is defined only by the claims and never bound by the specification. Those modifications and variations that may lead to equivalents of claimed elements are all included within the scope of the invention.

The present application hereby claims priority on Japanese Patent Application, Tokugan, No. 2013-258670 filed Dec. 13, 2013 in Japan and Japanese Patent Application, Tokugan, No. 2014-017103 filed Jan. 31, 2014 in Japan, the entire contents of which are hereby incorporated herein by reference.

1. A visually homogeneous and transparent optical wavelength conversion element comprising: a combination of organic photosensitizing molecules (A) and organic light-emitting molecules (B) that exhibits triplet-triplet annihilation; and an ionic liquid (C), the element being produced by dissolving and/or dispersing the combination in the ionic liquid (C), wherein water resulting from washing the ionic liquid (C) with a volume of ultrapure water that is 9 times as much as the volume of the ionic liquid (C) has a pH larger than 5.

2. The optical wavelength conversion element according to claim 1, wherein the organic photosensitizing molecules (A) have a local maximum absorption wavelength of from 500 nm to 700 nm.

3. The optical wavelength conversion element according to claim 1, wherein the organic photosensitizing molecules (A) have a structure containing no metal.

4. The optical wavelength conversion element according to claim 1, wherein the organic photosensitizing molecules (A) are a compound of general formula (1) 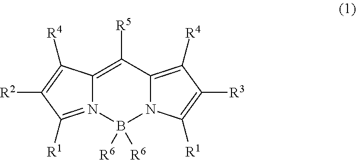
where each of R¹ to R⁵ is independently any substituent including a hydrogen atom, adjacent substituents (R¹ and R², R² and R⁴, R¹ and R³, and R³ and R⁴) may be joined together to form a five- or six-membered ring having any substituent including a hydrogen atom, and R⁶ is a halogen atom, a C₁-C₅ alkyl group that may contain a substituent, or a C₁-C₅ alkoxyl group that may contain a substituent.

5. The optical wavelength conversion element according to claim 4, wherein each of R¹ to R⁵ in general formula (1) is independently a hydrogen atom, a halogen atom, a C₁-C₄ aliphatic hydrocarbon group that may contain a substituent, a phenyl group that may contain a substituent, a phenoxy group that may contain a substituent, a thienyl group that may contain a substituent, a thienoxy group that may contain a substituent, a 2-carboxylethenyl group of general formula (2) 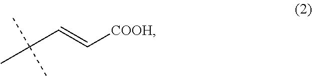
or
a 2-carboxyl-2-cyanoethenyl group of general formula (3)

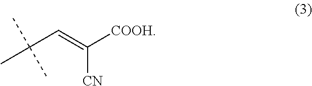

6. The optical wavelength conversion element according to claim 1, wherein the organic photosensitizing molecules (A) are a compound of general formula (4) 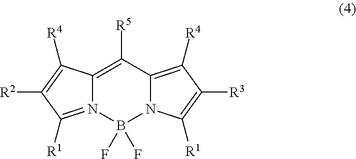
where each of R¹ and R⁴ is independently a C₁-C₃ alkyl group that may contain a substituent, each of R² and R³ is independently a hydrogen atom, a bromine atom, or an iodine atom, either one or both of R² and R³ is/are a bromine atom or an iodine atom, and R⁵ is a phenyl group that may contain a substituent.

7. The optical wavelength conversion element according to claim 1, further comprising a gelator (D).

8. The optical wavelength conversion element according to claim 7, wherein the element is in a gel state.

9. The optical wavelength conversion element according to claim 7, wherein the gelator (D) is an ionic gelator.

10. The optical wavelength conversion element according to claim 7, wherein the gelator (D) is a nonionic polymer.

11. A solar cell comprising the optical wavelength conversion element according to claim 1.

12. A photocatalyst comprising the optical wavelength conversion element according to claim 1.

13. A photocatalytic hydrogen and oxygen generating device comprising the optical wavelength conversion element according to claim 1.

14. A photon upconversion filter converting light of relatively long wavelengths to light of relatively short wavelengths,
the filter comprising:
the optical wavelength conversion element according to claim 1; and
a cell,
wherein the optical wavelength conversion element is sealed in the cell.
